(19) United States
(12) Patent Application Publication
(10) Pub. No.: US 2013/0001546 A1
(43) Pub. Date: Jan. 3, 2013

(54) DISPLAY DEVICE AND METHOD FOR PRODUCING ARRAY SUBSTRATE FOR DISPLAY DEVICE

(76) Inventors: Tsuyoshi Kamada, Osaka-shi (JP); Shigeru Aomori, Osaka-shi (JP); Tetsuya Ide, Osaka-shi (JP); Seiji Ohhashi, Osaka-shi (JP); Shohei Katsuta, Osaka-shi (JP)

(21) Appl. No.: 13/635,507

(22) PCT Filed: Mar. 18, 2011
(86) PCT No.: PCT/JP2011/056522

§ 371 Date: Sep. 17, 2012

(30) Foreign Application Priority Data
Mar. 26, 2010 (JP) 2010-072382

(51) Int. Cl. H01L 29/786; H01L 33/08

(52) U.S. Cl. 257/43; 438/34; 257/E29.273; 257/E33.062

(57) ABSTRACT

A display device includes: a plurality of stripe-shaped data electrodes that are formed on a first substrate and that extend in the column direction; a plurality of scanning lines and a plurality of reference signal lines that are formed on a second substrate and that extend in the row direction; a plurality of pixel electrodes that are formed on the second substrate and that are disposed in a matrix arrangement; a plurality of switching elements that are formed on the second substrate and in which on/off is controlled by the plurality of scanning lines, and that are disposed between the plurality of reference signal lines and the plurality of pixel electrodes; and an oxide semiconductor layer that is disposed between a source electrode and a drain electrode. The switching elements are formed so as to be disposed in the vicinity of a gate electrode on the oxide semiconductor layer, with an insulating layer interposed therebetween. The pixel electrodes are provided so as to be connected to the source electrode or the drain electrode. The source electrode or the drain electrode that is connected to the pixel electrode is made from the same material as the pixel electrode. The source electrode and the drain electrode are films formed at the same time.

### TECHNICAL FIELD

The present invention relates to a display device and to a method for producing an array substrate for a display device.

The subject application claims priority based on the patent application No. 2010-072382 filed in Japan on Mar. 26, 2010 and incorporates by reference herein the contents thereof.

### BACKGROUND ART

Reducing the number of process steps is effective in reducing the costs of large liquid crystal display televisions that incorporate active-matrix drive LCD panels. Current manufacturing processes for thin-film transistor (TFT) substrates for large LCD televisions require at least four or five photolithography process steps and two CVD (chemical vapor deposition) process steps. This processing represents a substantial limitation on the achievement of reducing process steps.

Thin-film transistors provided in a TFT substrate require at least three types of electrodes (source electrode, drain electrode, and gate electrode). Among other requirements, in a TFT transistor, the gate resistance must be low, the source/drain resistance must be low, the source/drain and gate must be insulated, and the pixel electrode must be transparent, connected to the drain, and insulated from the gate. Also, an a-Si thin-film transistor that is applied to a TFT substrate requires an n⁺ a-Si layer so that a Schottky barrier does not occur at the connection part with the electrode metal.

With the foregoing as a backdrop, a first example of the a-Si thin-film transistor manufacturing process currently applied to the manufacturing process for the TFT substrate will be described, based on FIG. 21A through 21F.

A first photolithography process step is performed in the case of forming a gate electrode 101 of a desired shape after forming a laminated film of Al and Mo over an insulating substrate 100, as shown in FIG. 21A. After that, CVD is used to laminate a gate insulating film 102 and an a-Si layer 103, which are made of SiN, and an n^{+a} a-Si layer (p-doped layer) 105, as shown in FIG. 21B.

Next, a second photolithography process step is performed on the a-Si layer 103 and the n⁺ a-Si layer 105 to perform element separation, and form an element part 106 above a location at the gate electrode 101, as shown in FIG. 21C. After that, a film (Mo/Al/Mo laminated film) is deposited for the formation of the source/drain, and channel etching and source/drain formation are performed. Then, when forming a channel 117, a source electrode 108, and a drain electrode 109 as shown in FIG. 21D, a third photolithography process step is performed. When performing the above-noted channel etching, it is necessary to stop the etching just before the film is removed, so that the entire a-Si layer 103 for the forming of the channel is not etched away.

Next, CVD is used to form a protective film 110 made of SiN, and a fourth photolithography process is performed to form a contact hole 111 that reaches the drain electrode 109, as shown in FIG. 21E. Then, after forming a transparent electrode film made of ITO (indium-tin oxide), a fifth photolithography process step is performed when forming a pixel electrode 112 that connects to the drain electrode 109 via the contact hole 111 as shown in FIG. 21F.

In this manner, in the first example of a process for manufacturing an a-Si thin-film transistor, five mask process steps and two CVD depositions are required.

Next, a second example of an a-Si thin-film transistor manufacturing process will be described, based on FIG. 22A through FIG. 22F.

A first photolithography process step is performed in the case of forming a gate electrode 121 of a desired shape after forming a laminated film of Al and Mo over an insulating substrate 120, as shown in FIG. 22A. After that, CVD is used to laminate a gate insulating film 122 made of SiN, an a-Si layer 123, and a protective film 125, as shown in FIG. 22B.

Next, a second photolithography process step is performed on the a-Si layer 123 and the protective film 125 to perform element separation, and an element part 126 is formed above a location at the gate electrode 121, as shown in FIG. 22C. After that, an n⁺ a-Si layer and a film (Mo/Al/Mo laminated film) are deposited for the purpose of forming the source/drain, and a source/drain is formed with a shape so as to partially cover the element part 126. Then, a third photolithography process step is performed when forming a source electrode 128 and a drain electrode 129, as shown in FIG. 22D. In the structure of the second example, an n⁺ a-Si layer 124 layer is interposed between the source electrode 128 and the element part 126 and between the drain electrode 129 and the element part 126. If this structure is used, it is not necessary to use advanced etching technology to stop etching just before the a-Si layer 103 is removed, as in the first example, thereby providing an advantage to this manufacturing method.

Next, CVD is used to form a protective film 130 of SiN, and a fourth photolithography process step is performed to form a contact hole 131 that reaches the drain electrode 129, as shown in FIG. 22E. Then, after forming an ITO (indium tin oxide) transparent electrode film, a fifth photolithography process step is performed when forming a pixel electrode 132 that connects to the drain electrode 129 via the contact hole 131 as shown in FIG. 22F.

In this manner, in the second example of a process for manufacturing an a-Si thin-film transistor, five mask process steps and two CVD depositions are required.

Next, a third example of an a-Si thin-film transistor manufacturing process will be described, based on FIG. 23A to FIG. 23F.

A first photolithography process step is performed in the case of forming a gate electrode 141 of a desired shape after forming a laminated film of Al and Mo over an insulating substrate 140, as shown in FIG. 23A. After that, CVD is used to laminate an insulating film 142 made of SiN, an a-Si layer 143, an n⁺ a-Si layer 145, and an electrode film (Mo/Al/Mo laminated film) 146 for forming a source/drain, as shown in FIG. 23B.

Next, as shown in FIG. 23C, a second photolithography process step is performed on the electrode film 146, the n⁺ a-Si layer 145, and the a-Si layer 143 to perform element separation, and an element part 144 is formed is formed above a location at the gate electrode 141. After that, channel etching and source/drain formation are performed. Then, when forming a channel 147, a source electrode 148, and a drain electrode 149 as shown in FIG. 23D, processing is done by half-tone exposure using a second photolithography process step, without increasing the number of photolithography process steps. When performing this half-tone exposure, the structure shown in FIG. 23D can be obtained by varying the film thickness of a resist 155 that partially remains and by performing ashing.

Next, after removing the resist, an SiN protective film 150 is formed and, using a third photolithography process step, a contact hole 151 that reaches the drain electrode 149 is formed, as shown in FIG. 23E. After forming an ITO (indium tin oxide) transparent electrode film, a fourth photolithography process step is used when forming a pixel electrode 152 that connects to the drain electrode 149 via the contact hole 151, as shown in FIG. 23F.

In this manner, in the third example of a process for manufacturing an a-Si thin-film transistor, four mask process steps and two CVD depositions are required. It is thought that, at present, the process for using four masks, such as in the third example, is the shortest process, and this is used.

Next, as a fourth example of a TFT substrate applied to a liquid crystal display device, the opposing-data type liquid crystal display device described in Patent Document 1 and as shown in FIG. 24 to FIG. 26, will be described.

In the liquid crystal display device of this example, pixel electrodes 161 are disposed in a matrix arrangement, so as to correspond to display regions of one substrate 160 for sandwiching a liquid crystal layer. A common bus line 163 is connected to the source sides of switching elements 162 connected to each of the pixel electrodes 161 arranged in the row direction (the X direction in FIG. 24). Also, a gate bus line 165 is connected to the gate sides of the switching elements 162 arranged in the row direction. An opposing side substrate 166 that sandwiches the liquid crystal has, formed thereon on the liquid crystal side thereof, a plurality of stripe-shaped data bus lines 167 that extend in the column direction (the Y direction in FIG. 24).

In the liquid crystal display device of this example, a reference signal voltage (common voltage) is applied to the pixel electrodes 161 from the common bus line 163, via the switching elements 162 that are placed in the on state by an input from the gate bus line 165. Then, data signals are input to the data bus lines 167. The orientation of the liquid crystal molecules that exist at the intersecting regions between the plurality of data bus lines 167 and the pixel electrodes 161 is, therefore, controlled so as to make a display.

A fifth example of a liquid crystal display device is a known liquid crystal display device having a panel structure equivalent to that of the above-described opposing-data type, and in which the drain electrodes and the source electrodes are made of a microcrystalline or polycrystalline n⁺Si layer (refer to Patent Document 2).

The a-Si thin-film transistor structure such as shown in FIG. 27 is disclosed as a structural example in Patent Document 2. In this structure, a drain layer 171 and a source layer 172 made of microcrystalline or polycrystalline n⁺Si layers are provided with a space therebetween on an insulating substrate 170 made of glass. Then, an a-Si:H layer (hydrogenated amorphous silicon layer) 173 is formed as a covering thereover, over which an SiN layer 175 and a gate electrode 176 are then formed.

The interconnect structure described in Patent Document 2, as shown in FIG. 28, has a plurality of scanning bus lines SB. Each of the scanning bus lines SB is connected to the gate G of a TFT, to the source S of which is connected the liquid crystal LC to the next position scanning bus line SB.

To obtain the thin-film transistor matrix for a liquid crystal display device of the fifth example, an n⁺Si layer 181 is formed over an insulating substrate 180, and the source electrodes and drain electrodes are patterned, as shown in FIG. 29A and FIG. 29B. Next, a semiconductor layer 182 is formed, a gate insulating film 183, an Al gate electrode 185 and a gate bus line are formed, and patterning is done with a desired shape, as shown in FIG. 29C. After that, an ITO film is deposited and, as shown in FIG. 29E and FIG. 29F, a display electrode 186 and a connecting part 187 are formed, thereby completing the thin-film transistor matrix.

Next, a sixth example of a liquid crystal display device is a known liquid crystal display device having a TFT 200 such as shown in FIG. 30. In this liquid crystal display device, pixel electrodes 191 are provided in a matrix arrangement on a main substrate 190. Then, between the pixel electrodes 191, scan signal lines 192 and reference signal lines 193 are provided in a row. Then, a gate insulating film 196 and a semiconductor layer 197 are formed so as to cover a gate terminal 195 formed on part of the scan signal line 192. Then, a part of the pixel electrode 191 is connected with one side of the semiconductor layer 197, as the drain terminal, as 191a. Then, a connecting line 198 connected to the reference signal line 193 is connected with the other side of the semiconductor layer 197, as a source terminal 198a. In this liquid crystal display device, the pixel electrode 191 and connecting line 198 and the source terminal 198a and drain terminal 191a are made of n⁺a-Si:H or of microcrystalline n⁺ silicon (refer to Patent Document 3).

### PRIOR ART DOCUMENTS

### Patent Documents

Patent Document 1: Japanese Unexamined Patent Application, First Publication No. S62-133478
Patent Document 2: Japanese Unexamined Patent Application, First Publication No. S63-309926
Patent Document 3: Japanese Unexamined Patent Application, First Publication No. 2000-258795

### DISCLOSURE OF INVENTION

### Problem to be Solved by the Invention

If the conventional manufacturing processes for an a-Si thin-film transistor are reconsidered, three types of thin-film transistor electrodes are required. Also, considering the requirement for the gate and source/drain resistances to be low, the pixel electrodes to be transparent, and that gate and source/drain lamination is essential, if three metal layers is required, formation of metal layer patterns three times is required. Also, considering two layers of interlayer insulating film, one formation of a hole-opening pattern in the insulating film is required. If it is assumed that film deposition by CVD at least two times and a minimum of four photolithography process step are required, it is thought that above-described four mask processes represent the shortest process at present.

However, recently there arises a need for further attempts to reduce the process step in the manufacturing TFT substrates for LCD televisions. Given this, the inventors performed a reconsideration of the structures of conventionally known liquid crystal display devices and the thin-film transistors applied therein.

In the above-described opposing-data type of liquid crystal display device described based on FIG. 24 to FIG. 26 as the fourth example, there is no lamination of the gate bus line 165 with the data bus line 167. Because there are few shorting faults between laminations and there are no locations where interconnects pass over steps, it is difficult for shorts to occur, this presenting the advantages of being able to inspect and repair individual substrates, and to achieve a high yield. Also, considering the substrate 160 on which the switching elements 162 are formed, it is possible to apply high-resistance source and drain interconnects, so that there is hope of the possibility of deposition together with the pixel electrodes.

Also, in the liquid crystal display device described above based on FIG. 27 to FIG. 29F as the fifth example, two CVD depositions are sufficient to deposit the n layer and the insulating film/a-Si layer. However, the a-Si layer is unprotected with respect to light from the glass substrate rear surface side, and there is the problem of light leakage.

In the liquid crystal display device described above based on FIG. 30 as the sixth example, two CVD depositions are sufficient to deposit the n⁺a-Si layer and the insulating film/a-Si layer. However, the n⁺a-Si layer cannot be said to be transparent, and transmissivity loss occurs. Also, if the n⁺a-Si layer is excessively thin, problems such as breaks, reduced reliability, and high resistance occur.

Based on the investigation of liquid crystal display device having conventional structures such as noted above, the inventors have made specific refinements in the structure of thin-film transistors regarding the above-described opposing-data type liquid crystal display device. By doing this, it was learned that manufacturing is possible by a process that is simpler than the conventional manufacturing process and that it is possible to provide a display device in which it is difficult for transmissivity loss to occur and in which it is difficult for the problem of light leakage to occur, this leading to the present invention.

Also, based on the above-described investigation, the inventors discovered that manufacturing is possible by a process that is simpler than the conventional manufacturing process and that it is possible to provide a manufacturing method for a display device in which it is difficult for transmissivity loss to occur and in which it is difficult for the problem of light leakage to occur, this leading to the present invention.

### Means to Solve the Problem

(1) A first aspect of the present invention is a display device including:

a first substrate;

a second substrate that is disposed in opposition to the first substrate;

a display medium layer that is provided between the first substrate and the second substrate;

a plurality of stripe-shaped data electrodes that are formed on the first substrate and that extend in the column direction;

a plurality of scanning lines and a plurality of reference signal lines that are formed on the second substrate and that extend in the row direction;

a plurality of pixel electrodes that are formed on the second substrate and that are disposed in a matrix arrangement;

a plurality of switching elements that are formed on the second substrate and in which on/off is controlled by the plurality of scanning lines, and that are disposed between the plurality of reference signal lines and the plurality of pixel electrodes; and

an oxide semiconductor layer that is disposed between a source electrode and a drain electrode;

wherein the switching elements are formed so as to be disposed in the vicinity of a gate electrode on the oxide semiconductor layer, with an insulating layer interposed therebetween;

the pixel electrodes are provided so as to be connected to the source electrode or the drain electrode;

the source electrode or the drain electrode that is connected to the pixel electrode is made from the same material as the pixel electrode; and

the source electrode and the drain electrode are films formed at the same time.

(2) In the first aspect of the present invention, by scanning the scanning lines, on/off control of the switching elements that are disposed along the corresponding scanning lines may be performed;

a reference signal voltage may be applied to the pixel electrodes from the reference signal lines, via the switching elements that are placed in the on state; and

each of data signals corresponding to the plurality of the data electrodes may be input, thereby controlling a molecular orientation or a luminescence of the display medium layer that is interposed between the pixel electrodes and the data electrodes to which voltages are applied, so as to make a display.

(3) In the first aspect of the present invention, the pixel electrodes, the drain electrodes, and the source electrodes may be made of an indium-gallium-zinc oxide reduced substance.

(4) In the first aspect of the present invention, the pixel electrodes, the drain electrodes, and the source electrodes and the reference signal lines and connecting lines that connect thereto and the reference signal lines may be all made of indium-gallium-zinc oxide; and wherein the oxide semiconductor layer may be made of indium-gallium-zinc oxide.

(5) In the first aspect of the present invention, the display device may further provide with a light-emitting diode backlight.

(6) In the first aspect of the present invention, the reference signal lines, the source electrodes or the drain electrodes of the switching elements connected to the reference signal lines, and the pixel electrodes and the drain electrodes or source electrodes of the switching elements connected to the pixel electrodes may be all made of a transparent electrically conductive film, and

the oxide semiconductor layer interposed between the source electrodes and the drain electrodes may be made of indium-gallium-zinc oxide.

(7) In the first aspect of the present invention, the plurality of reference signal lines, the source electrodes or drain electrodes of switching elements connected thereto, the pixel electrodes, and the drain electrodes or the source electrodes of switching elements connected to the pixel elements may be all formed on the second substrate,

an insulating film may be formed that covers the source electrodes, the drain electrodes, and the oxide semiconductor layer interposed therebetween, and

a gate electrode may be formed on the insulating film.

(8) In the first aspect of the present invention, a scanning line including the gate electrode and the reference signal line may be formed on the second substrate, an insulating film may be formed that covers the scanning line and the reference signal line, an oxide semiconductor layer may be formed over the insulating film and over the gate electrode, and a source electrode and a drain electrode and a pixel connected to any one thereof may be formed on the insulating film.

(9) In the first aspect of the present invention, a scanning line including the gate electrode and the reference signal line may be formed on the second substrate,

an insulating film may be formed that covers the scanning line and the reference signal line,

an oxide semiconductor layer may be formed over the insulating film and over the gate electrode,

a source electrode and a drain electrode and a pixel connected to any one thereof may be formed on the insulating film, and

wherein the oxide semiconductor layer may be made of an indium-gallium-zinc oxide, and

the pixel electrode, and the source electrode and the drain electrode may be made of an indium-gallium-zinc oxide reduced substance.

(10) A second aspect of the present invention is a method for manufacturing an array substrate, the method including:

on a second substrate disposed so as to be in opposition with a first substrate, forming a reference signal line and a source electrode or a drain electrode connected to the reference signal line, a pixel electrode, and a drain electrode or a source electrode connected to the pixel electrode, using a transparent electrically conductive material;

forming an oxide semiconductor layer so as to connect to the source electrode and the drain electrode;

forming an insulating film on the oxide semiconductor layer; and

forming a scanning line including a gate electrode on the second substrate so that the gate electrode is positioned on an insulating film between the source electrode and the drain electrode.

(11) In the second aspect of the present invention, the gate electrode and the scanning line may be metal interconnects made of a metal material.

(12) A third aspect of the present invention is a method for manufacturing an array substrate, the method including: on a second substrate disposed so as to be in opposition with a first substrate, forming a pixel electrode and a source electrode or a drain electrode connected to the pixel electrode, using a transparent electrically conductive material; forming an oxide semiconductor layer so as to connect to the source electrode and the drain electrode; forming an insulating film on the oxide semiconductor layer; forming a scanning line including a gate electrode on the second substrate so that the gate electrode is positioned on an insulating film between the source electrode and the drain electrode; and forming, on the insulating film, a reference signal line that connects to the one of the source electrode and the drain electrode that is not connected to the pixel electrode.

(13) In the third aspect of the present invention, the scanning line, the gate electrode and the reference signal line may be metal interconnects made of a metal material.

(14) A fourth aspect of the present invention is a method for manufacturing an array substrate, the method including:

on a second substrate disposed so as to be in opposition with a first substrate, forming a reference signal line, a gate electrode, and a scanning line;

forming an insulating film so as to cover the reference signal line, the gate electrode, and the scanning line;

forming an oxide semiconductor layer on the insulating film on the gate electrode; and

forming a pixel electrode connected to one electrode of the source electrode and the gate electrode that sandwich the oxide semiconductor layer on the gate electrode from both sides.

(15) In the fourth aspect of the present invention, the scanning line, the gate electrode, and the reference signal line may be metal interconnects made of a metal material.

(16) In the fourth aspect of the present invention, a channel-protection film may be formed over the oxide semiconductor layer after forming the oxide semiconductor layer,

a film may be deposited for formation of the source electrode and the gate electrode, and

the film may be patterned to form the source electrode and the gate electrode.

(17) A fifth aspect of the present invention is a method for manufacturing an array substrate, the method including:

on a second substrate disposed so as to be in opposition with a first substrate, forming a reference signal line, a gate electrode, and a scanning line;

forming an insulating film so as to cover the reference signal line, the gate electrode, and the scanning line;

forming an indium-gallium-zinc oxide layer so as to occupy the insulating film over the gate electrode, a pixel electrode formation position, a gate electrode formation position, and a source electrode formation position; and

reducing the part of the indium-gallium-zinc oxide layer other than the position over the gate electrode to make it conductive.

(18) In the fifth aspect of the present invention, plasma processing in a hydrogen atmosphere may be performed as the reducing of the indium-gallium-zinc oxide layer.

(19) In the fifth aspect of the present invention, the scanning line, the gate electrode, and the reference signal line may be metal interconnects made of a metal material.

(20) In the second, third, fourth, or fifth aspect of the present invention, the method may include:

forming a display medium layer between the first substrate and the second substrate;

forming, on the first substrate, a plurality of stripe-shaped data electrodes extending in a column direction;

forming, of the second substrate, a plurality of scanning lines and a plurality of reference signal lines extending in a row direction;

forming, on the second substrate, a plurality of pixel electrode disposed in a matrix arrangement;

forming, on the second substrate, a plurality of switching elements that are on/off controlled by the plurality of scanning lines and that also are provided between the plurality of reference signal lines and the plurality of pixel electrodes; and

forming, on the second substrate, the reference signal lines, the pixel electrodes, and the switching elements.

### Effect of the Invention

The present invention relates to an opposing-data type display device on one of the substrates of which are provided stripe-shaped data electrodes, and on the other substrate of which are provided pixel electrodes and switching elements that are disposed in a matrix arrangement, scanning lines for the purpose of selecting the switching elements, and reference signal lines for the purpose of applying a voltage to the pixel electrodes. In this display device, the switching elements are constituted by providing an oxide semiconductor layer between the source electrodes and the drain electrodes. The pixel electrodes and the drain electrodes or source electrodes connected thereto are films made from the same material and also formed by deposition at the same time. For this reason, it is possible to reduce the number of process steps to deposit the electrodes, while effectively using an oxide semiconductor layer in which leakage current caused by light does not occur. Also, it is possible to reduce the photolithography process steps when manufacturing an array substrate including switching elements, thereby achieving a reduced process steps.

### BRIEF DESCRIPTION OF THE DRAWINGS

FIG. 1 is a drawing showing the constitution of an embodiment of a display device according to the present invention.

FIG. 2 is a drawing showing the constitution of an example of the circuit constitution of the opposing-side substrate provided in the display device of the same embodiment.

FIG. 3 is a drawing showing the constitution of an example of the circuit constitution of the element-side substrate provided in the display device of the same embodiment.

FIG. 4 is a drawing showing the equivalent circuit constitution of the part that includes the pixel electrodes and the switching elements of the circuit constitution of the element-side substrate provided in the display device of the same embodiment.

FIG. 5 is a drawing showing the constitution of an example of the circuit constitution if the two substrates provided in the display device of the same embodiment are joined.

FIG. 6A is a plan view showing the first embodiment of a thin-film transistor provided in the same display device.

FIG. 6B is a plan view of the terminal part in the first embodiment of a thin-film transistor provided in the same display device.

FIG. 7 is a cross-sectional view along the line B₁-B₂ in the thin-film transistor shown in FIG. 6A.

FIG. 8A is a partial plan view of main parts showing a second embodiment of a thin-film transistor provided in the same display device.

FIG. 8B is a plan view showing the terminal part in the second embodiment of the thin-film transistor provided in the same display device.

FIG. 9 is a cross-sectional view along the line B₃-B₄ in the thin-film transistor shown in FIG. 8A.

FIG. 10 is cross-sectional view along the line B₅-B₆ in the thin-film transistor shown in FIG. 8A.

FIG. 11A is a drawing showing an example of a method for manufacturing the thin-film transistor of a second embodiment, which is a plan view that shows the condition in which the film for the source/drain has been formed.

FIG. 11B is a drawing showing an example of the method for manufacturing the thin-film transistor of the second embodiment, which is a cross-sectional view along the line B₇-B₈ in FIG. 11A.

FIG. 11C is a drawing showing an example of the method for manufacturing the thin-film transistor of the second embodiment, which is a cross-sectional view of a different part, along the line B₉-B₁₀ in FIG. 11A.

FIG. 11D is a drawing showing an example of the method for manufacturing the thin-film transistor of the second embodiment, which is a plan view that shows the condition in which an insulating film has been formed.

FIG. 11E is a drawing showing an example of the method for manufacturing the thin-film transistor of the second embodiment, which is a cross-sectional view along the line B₁₁-B₁₂ in FIG. 11D.

FIG. 11F is a drawing showing an example of the method for manufacturing the thin-film transistor of the second embodiment, which is a cross-sectional view along the line B₁₃-B₁₄ in FIG. 11D.

FIG. 11G a drawing showing an example of the method for manufacturing the thin-film transistor of the second embodiment, which is a plan view that shows the condition in which the gate electrode has been formed.

FIG. 11H is a drawing showing an example of the method for manufacturing the thin-film transistor of the second embodiment, which is a cross-sectional view along the line B₁₅-B₁₆ in FIG. 11G.

FIG. 11I is a drawing showing an example of the method for manufacturing the thin-film transistor of the second embodiment, which is a cross-sectional view along the line B₁₇-B₁₈ in FIG. 11G.

FIG. 12A is a partial plan view of main parts showing a third embodiment of a thin-film transistor provided in the same display device.

FIG. 12B is a plan view of the terminal part of the third embodiment of the thin-film transistor provided in the same display device.

FIG. 13 is a cross-sectional view along the line B₁₉-B₂₀ in FIG. 12A.

FIG. 14A is a drawing showing an example of the method for manufacturing the thin-film transistor of the third embodiment, which is a plan view that shows the condition in which the film for gate/common formation has been deposited.

FIG. 14B is a drawing showing an example of the method for manufacturing the thin-film transistor of the third embodiment, which is a plan view that shows the terminal part.

FIG. 14C is a drawing showing an example of the method for manufacturing the thin-film transistor of the third embodiment, which is a cross-section along the line B₂₁-B₂₂ in FIG. 14A.

FIG. 14D is a drawing showing an example of the method for manufacturing the thin-film transistor of the third embodiment, which is a plan view that shows the condition in which the insulating film, an oxide semiconductor film, and a protective film have been formed.

FIG. 14E is a drawing showing an example of the method for manufacturing the thin-film transistor of the third embodiment, which is a cross-sectional view of the terminal part.

FIG. 14F is a drawing showing an example of the method for manufacturing the thin-film transistor of the third embodiment, which is a cross-sectional view along the line B₂₃-B₂₄ in FIG. 14D.

FIG. 14G is a drawing showing an example of the method for manufacturing the thin-film transistor of the third embodiment, which is a plan view that shows the etched condition.

FIG. 14H is a drawing showing an example of the method for manufacturing the thin-film transistor of the third embodiment, which is a cross-sectional view of the terminal part in the condition of the etching done as in FIG. 14G.

FIG. 14I is a drawing showing an example of the method for manufacturing the thin-film transistor of the third embodiment, which is a cross-sectional view along the line B₂₅-B₂₆ in FIG. 14G.

FIG. 14J is a drawing showing an example of the method for manufacturing the thin-film transistor of the third embodiment, which is a plan view that shows the condition in which the pixel electrode has been formed.

FIG. 14K is a drawing showing an example of the method for manufacturing the thin-film transistor of the third embodiment, which is a cross-sectional view of the terminal part in the condition of the pixel electrode in FIG. 14J has been formed.

FIG. 14L is a drawing showing an example of the method for manufacturing the thin-film transistor of the third embodiment, which is a cross-sectional view along the line B₂₇-B₂₈ in FIG. 14J.

FIG. 15A is a partial plan view of main parts showing a fourth embodiment of a thin-film transistor provided in the same display device.

FIG. 15B is a plan view of the terminal part in a fourth embodiment of the thin-film transistor provided in the same display device.

FIG. 16 is a cross-sectional view along the line B₂₉-B₃₀ in FIG. 15A.

FIG. 17A is a drawing showing an example of the method for manufacturing the thin-film transistor of the fourth embodiment, which is a plan view that shows the condition in which the film for gate/common formation has been deposited.

FIG. 17B is a drawing showing an example of the method for manufacturing the thin-film transistor of the fourth embodiment, which is a plan view that shows the terminal part.

FIG. 17C is a drawing showing an example of the method for manufacturing the thin-film transistor of the fourth embodiment, which is a cross-sectional view along the line B₃₁-B₃₂ in FIG. 17A.

FIG. 17D is a drawing showing an example of the method for manufacturing the thin-film transistor of the fourth embodiment, which is a plan view that shows the condition in which an insulating film and an oxide semiconductor film have been formed.

FIG. 17E is a drawing showing an example of the method for manufacturing the thin-film transistor of the fourth embodiment, which is a cross-sectional view that shows the terminal part in the condition in which the insulating film and the oxide semiconductor film of FIG. 17D have been formed.

FIG. 17F is a drawing showing an example of the method for manufacturing the thin-film transistor of the fourth embodiment, which is a cross-sectional view along the line B₃₃-B₃₄ in FIG. 17D.

FIG. 17G is a drawing showing an example of the method for manufacturing the thin-film transistor of the fourth embodiment, which is a plan view that shows the etched condition.

FIG. 17H is a drawing showing an example of the method for manufacturing the thin-film transistor of the fourth embodiment, which is a cross-sectional view of the terminal part in the condition of the etching done as in FIG. 17G.

FIG. 17I is a drawing showing an example of the method for manufacturing the thin-film transistor of the fourth embodiment, which is a cross-sectional view of the main parts along the line B₃₅-B₃₆ in FIG. 17G.

FIG. 17J is a drawing showing an example of the method for manufacturing the thin-film transistor of the fourth embodiment, which is a plan view that shows the condition in which the pixel electrode has been formed.

FIG. 17K is a drawing showing an example of the method for manufacturing the thin-film transistor of the fourth embodiment, which is a cross-sectional view of the terminal part in the condition in which the pixel electrode FIG. 17J has been formed.

FIG. 17L is a drawing showing an example of the method for manufacturing the thin-film transistor of the fourth embodiment, which is a cross-sectional view along the line B₃₇-B₃₈ in FIG. 17A.

FIG. 18A is a partial plan view of main parts showing a fifth embodiment of a thin-film transistor provided in the same display device.

FIG. 18B is a plan view of the terminal part in a fifth embodiment of the thin-film transistor provided in the same display device.

FIG. 19 is a cross-sectional view along the line B₃₉-B₄₀ in FIG. 18A.

FIG. 20A is a drawing showing an example of the method for manufacturing the thin-film transistor of the fifth embodiment, which is a plan view that shows the condition in which the film for gate/common formation has been deposited.

FIG. 20B is a drawing showing an example of the method for manufacturing the thin-film transistor of the fifth embodiment, which is a plan view that shows the terminal part.

FIG. 20C is a drawing showing an example of the method for manufacturing the thin-film transistor of the fifth embodiment, which is a cross-sectional view of the main parts along the line B₄₁-B₄₂ in FIG. 20A.

FIG. 20D is a drawing showing an example of the method for manufacturing the thin-film transistor of the fifth embodiment, which is a plan view that shows the condition in which the insulating film and an oxide semiconductor film have been formed.

FIG. 20E is a drawing showing an example of the method for manufacturing the thin-film transistor of the fifth embodiment, which is a cross-sectional view that shows the terminal part in the condition in which the insulating film and the oxide semiconductor film of FIG. 20D have been formed.

FIG. 20F is a drawing showing an example of the method for manufacturing the thin-film transistor of the fifth embodiment, which is a cross-sectional view of the main parts along the line B₄₃-B₄₄ in FIG. 20D.

FIG. 20G is a drawing showing an example of the method for manufacturing the thin-film transistor of the fifth embodiment, which is a plan view that shows the condition in which the pixel electrode has been formed.

FIG. 20H is a drawing showing an example of the method for manufacturing the thin-film transistor of the fifth embodiment, which is a cross-sectional view of the terminal part in the condition in which the pixel electrode in FIG. 20G has been formed.

FIG. 20I is a drawing showing an example of the method for manufacturing the thin-film transistor of the fifth embodiment, which is a cross-sectional view along the line B₄₅-B₄₆ in FIG. 20G.

FIG. 20J is a drawing showing an example of the method for manufacturing the thin-film transistor of the fifth embodiment, which is a plan view that shows the condition in which plasma processing has been done.

FIG. 20K is a drawing showing an example of the method for manufacturing the thin-film transistor of the fifth embodiment, which is a cross-sectional view of the terminal part in the condition in which the plasma processing of FIG. 20J has been done.

FIG. 20L is a drawing showing an example of the method for manufacturing the thin-film transistor of the fifth embodiment, which is a cross-sectional view along the line B₄₇-B₄₈ in FIG. 20J.

FIG. 21A is a drawing showing a first example of a process for manufacturing an a-Si type thin-film transistor applied to the manufacturing of a current TFT substrate, this being a cross-sectional view that shows the condition in which a gate has been formed on the substrate.

FIG. 21B is a drawing showing the first example of the process for manufacturing the a-Si type thin-film transistor applied to the manufacturing of the current TFT substrate, this being a cross-sectional view that shows the condition in which a gate insulating film, an a-Si film, and an n⁺a-Si film have been formed on the substrate.

FIG. 21C is a drawing showing the first example of the process for manufacturing the a-Si type thin-film transistor applied to the manufacturing of the current TFT substrate, this being a cross-sectional view that shows the condition in which the gate insulating film, the a-Si film, and the n⁺a-Si film have performed element separation.

FIG. 21D is a drawing showing the first example of the process for manufacturing the a-Si type thin-film transistor applied to the manufacturing of the current TFT substrate, this being a cross-sectional view that shows the condition in which a channel has been formed.

FIG. 21E is a drawing showing the first example of the process for manufacturing the a-Si type thin-film transistor applied to the manufacturing of the current TFT substrate, this being a cross-sectional view that shows the condition in which a protective film has been formed.

FIG. 21F is a drawing showing the first example of the process for manufacturing the a-Si type thin-film transistor applied to the manufacturing of the current TFT substrate, this being a cross-sectional view that shows the condition in which a pixel electrode has been formed.

FIG. 22A is a drawing showing a second example of a process for manufacturing an a-Si type thin-film transistor applied to the manufacturing of a current TFT substrate, this being a cross-sectional view that shows the condition in which a gate has been formed on the substrate.

FIG. 22B is a drawing showing the second example of the process for manufacturing the a-Si type thin-film transistor applied to the manufacturing of the current TFT substrate, this being a cross-sectional view that shows the condition in which a gate electrode, an a-Si film, and a protective film have been formed on the substrate.

FIG. 22C is a drawing showing the second example of the process for manufacturing the a-Si type thin-film transistor applied to the manufacturing of the current TFT substrate, this being a cross-sectional view that shows the condition in which the protective film and the a-Si film have performed element separation.

FIG. 22D is a drawing showing the second example of the process for manufacturing the a-Si type thin-film transistor applied to the manufacturing of the current TFT substrate, this being a cross-sectional view that shows the condition in which an n⁺a-Si film and a source/drain have been formed.

FIG. 22E is a drawing showing the second example of the process for manufacturing the a-Si type thin-film transistor applied to the manufacturing of the current TFT substrate, this being a cross-sectional view that shows the condition in which a protective film has been formed.

FIG. 22F is a drawing showing the second example of the process for manufacturing the a-Si type thin-film transistor applied to the manufacturing of the current TFT substrate, this being a cross-sectional view that shows the condition in which a pixel electrode has been formed.

FIG. 23A is a drawing showing a third example of a process for manufacturing an a-Si type thin-film transistor applied to the manufacturing of a current TFT substrate, this being a cross-sectional view that shows the condition in which a gate has been formed on the substrate.

FIG. 23B is a drawing showing the third example of the process for manufacturing the a-Si type thin-film transistor applied to the manufacturing of the current TFT substrate, this being a cross-sectional view that shows the condition in which a gate insulating film, an a-Si film, an n⁺a-Si film, and a film for forming the source/drain have been formed on the substrate.

FIG. 23C is a drawing showing the third example of the process for manufacturing the a-Si type thin-film transistor applied to the manufacturing of the current TFT substrate, this being a cross-sectional view that shows the condition in which the a-Si film, the n⁺a-Si film, and the film for forming the drain/source have performed element separation.

FIG. 23D is a drawing showing the third example of the process for manufacturing the a-Si type thin-film transistor applied to the manufacturing of the current TFT substrate, this being a cross-sectional view that shows the condition in which a channel has been formed.

FIG. 23E is a drawing showing the third example of the process for manufacturing the a-Si type thin-film transistor applied to the manufacturing of the current TFT substrate, this being a cross-sectional view that shows the condition in which a protective film has been formed.

FIG. 23F is a drawing showing the third example of the process for manufacturing the a-Si type thin-film transistor applied to the manufacturing of the current TFT substrate, this being a cross-sectional view that shows the condition in which a pixel electrode has been formed.

FIG. 24 is a drawing showing a fourth example of a TFT substrate applied to a liquid display device, this being a drawing that shows the constitution of an opposing-data type liquid crystal display device.

FIG. 25 is a drawing describing the same liquid crystal display device.

FIG. 26 is an equivalent circuit diagram of the same liquid crystal display device.

FIG. 27 is a drawing showing a fifth example of a TFT substrate applied to a display device, this being a drawing that shows the constitution of the thin-film transistor part in an opposing-data type liquid crystal display device.

FIG. 28 is an equivalent circuit diagram of the same liquid crystal display device.

FIG. 29A is a drawing showing an example of a process for manufacturing the opposing-data type liquid crystal display device shown in FIG. 27 and FIG. 28, this being a cross-sectional view that shows the condition in which a source/drain is formed on the substrate.

FIG. 29B is a drawing showing an example of a process for manufacturing the opposing-data type liquid crystal display device shown in FIG. 27 and FIG. 28, this being a plan view that shows the condition in which the source/drain of FIG. 29A is formed.

FIG. 29C is a drawing showing an example of the process for manufacturing the opposing-data type liquid crystal display device shown in FIG. 27 and FIG. 28, this being a cross-sectional view that shows the condition in which the a-Si film and n⁺a-Si films have performed element separation and the gate electrode and gate bus line patterns have been formed.

FIG. 29D is a drawing showing an example of the process for manufacturing the opposing-data type liquid crystal display device shown in FIG. 27 and FIG. 28, this being a plan view that shows the condition in which the a-Si film and n⁺a-Si films in FIG. 29C has performed element separation, and in which the gate electrode and gate bus line patterns are formed.

FIG. 29E is a drawing showing an example of the process for manufacturing the opposing-data type liquid crystal display device shown in FIG. 27 and FIG. 28, this being a cross-sectional view that shows the condition in which the pixel electrode is formed.

FIG. 29F is a drawing showing an example of the process for manufacturing the opposing-data type liquid crystal display device shown in FIG. 27 and FIG. 28, this being a plan view that shows the condition in which the pixel electrode is formed.

FIG. 30 is a drawing showing a sixth example of a TFT substrate applied to a liquid crystal display device, this being a cross-sectional view that shows the thin-film transistor part of an opposing-data type liquid crystal display device.

### BEST MODE FOR CARRYING OUT THE INVENTION

An embodiment of a liquid crystal display device according to the present invention will be described below, with references made to the drawings.

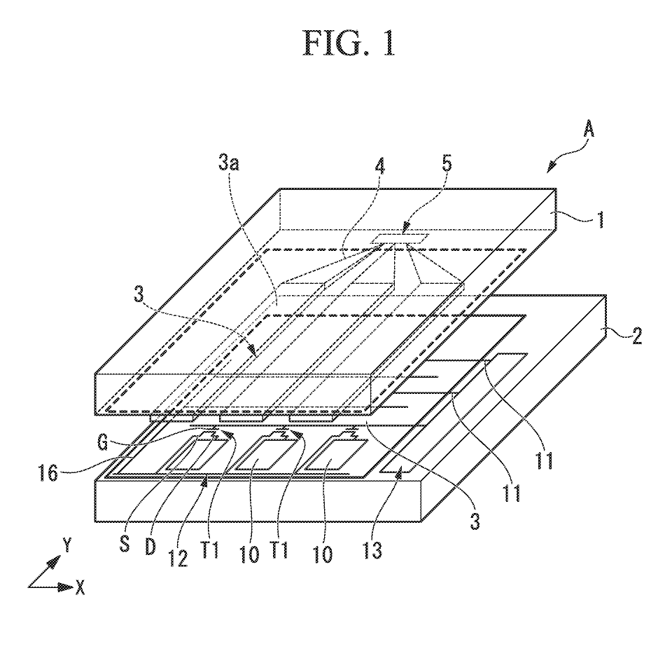

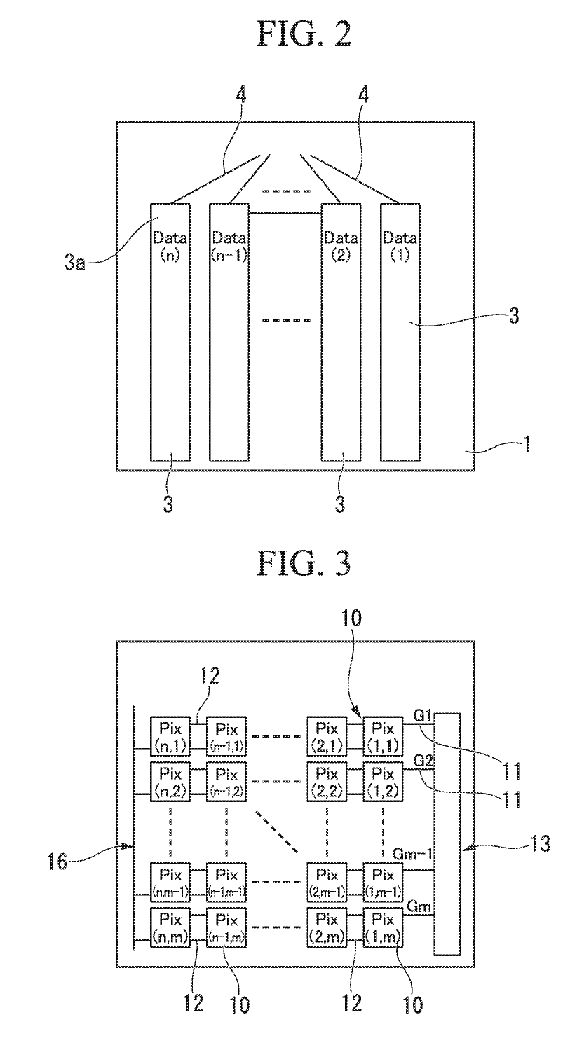

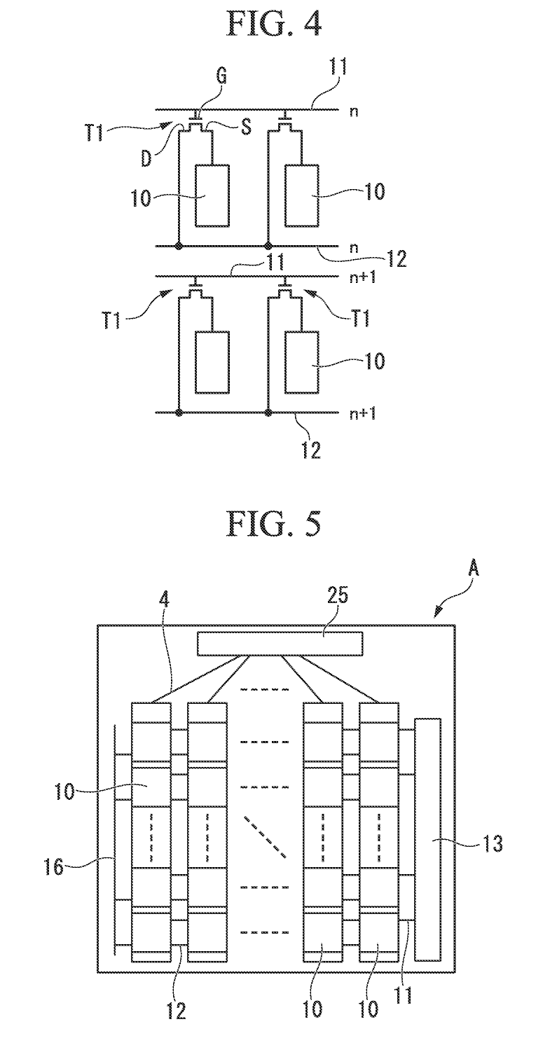

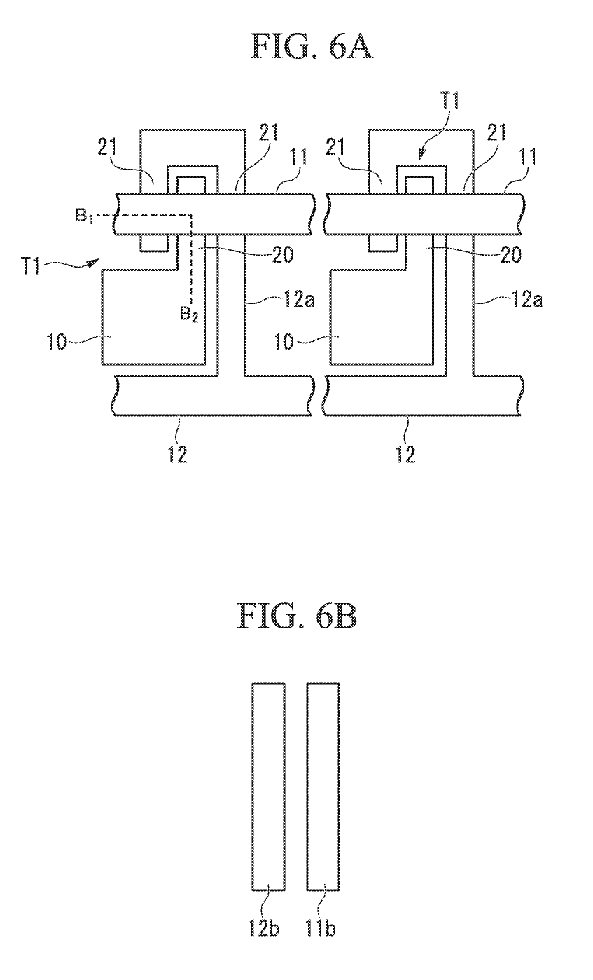

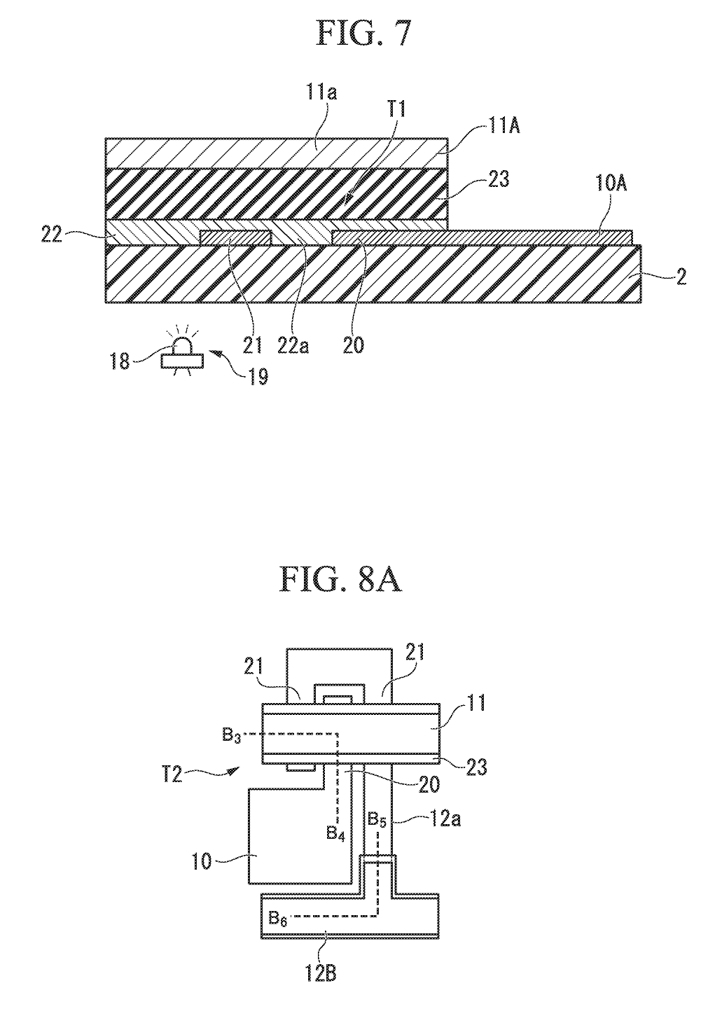

The display device of the present embodiment is applied to an opposing-data supply type display device in which a display medium layer, such as a liquid crystal layer, is sandwiched between a pair of substrates. FIG. 1 shows the pair of substrates in the opposing condition and generally shows the interconnections formed on both substrates. FIG. 2 shows the interconnects on the opposing-side substrate. FIG. 3 shows the interconnects on the element-side substrate. FIG. 4 shows the interconnect structure surrounding the pixel electrode. FIG. 5 is a simplified drawing showing the overall circuit as a display device, with the two substrates combined. FIG. 6A and FIG. 6B show an example of the constitution of the thin-film transistor as a switching element applied to a display device. FIG. 7 is a cross-sectional view of main parts of the same thin-film transistor.

### <Constitution of the Display Device>

In the display device A of the present embodiment, as shown in FIG. 1, the constitution is such that a first substrate 1 and a second substrate 2 that are made of rectangularly shaped glass or the like are disposed in mutual opposition, so that a liquid crystal layer, an organic EL thin film layer or the like is sandwiched therebetween as a display medium layer. If the display medium layer sandwiched between the first substrate 1 and the second substrate 2 is a liquid crystal layer, a sealing material is disposed around the peripheral part of the first substrate 1 and the second substrate 2, the liquid crystal layer being sealed between the two substrates 1 and 2 and the sealing material. However, the sealing material and sealing structure are omitted from FIG. 1, only the main parts of the interconnect elements and electrode parts formed on the substrate being shown. The first substrate 1 and the second substrate 2 are usually constituted of transparent glass substrates or the like. In the case of a reflective type of display, however, one of the substrates may not have transparency.

As shown in FIG. 1, a plurality of stripe-shaped data electrodes 3 extending in the column direction (Y direction in FIG. 1) are provided on the surface of the display medium layer side of the first substrate 1. The one ends 3a in the length direction of these data electrodes 3 are extended via extension interconnects 4 to the peripheral part side of the first substrate 1, forming a first substrate side terminal collection part 5. The first substrate side terminal collection part 5 is partitioned as a region in which terminal joinings are made with a drive IC 25 (FIG. 5), which will be described later, or a flexible printed board (FPC board) on which a drive IC and electronic components are mounted.

In the second substrate 2 side, as shown in FIG. 1, a plurality of rectangularly shaped pixel electrodes 10 are formed in a matrix arrangement on the display medium layer side surface (upper surface) of the second substrate 2.

Of the pixel electrodes 10, a plurality of pixel electrodes 10 that are arranged with a prescribed spacing in the column direction (Y direction) are disposed so as to be opposite a data electrode 3 of the first substrate 1. The spacing of pixel electrodes 10 arranged in the row direction (X direction) is made the same as the spacing of the data electrodes 3 formed on the first substrate 1. Also, in FIG. 1, in order to simplify the arrangement condition of the pixel electrodes 10, only three pixel electrodes are illustrated. In actuality, however, in accordance with the resolution of display device to which application is made, an arbitrary number n of pixel electrodes in the row direction and an arbitrary number m of pixel electrodes in the column direction, as shown in FIG. 3, are disposed in a matrix arrangement so as to constitute the display device. For example, in the case of a display device having resolution for the full HD standard, in the color display constitution using a RGB color filter, n would be 1920×3, and m would be 1080. In this embodiment, the number n×m of arranged pixel electrodes 10 can be adjusted as appropriate to the resolution required of the display device. In the present embodiment, what is shown in no more than one example. The number arranged can be adopted as appropriate to the required resolution of the display device.

Next, in the vicinity of the pixel electrodes 10 disposed in a matrix arrangement on the second substrate 2, a plurality of scanning line 11 extending in the row direction (X direction) and a plurality of reference signal lines 12 extending in the row direction are formed so as to run along each of the pixel electrodes 10 arranged in a matrix.

The scanning lines 11 each pass by the vicinity of the pixel electrodes 10 and are formed to extend up to the edge part of the second substrate 2, and are each connected to the output terminals of the gate driver 13 that is disposed so as to extend in the column direction (Y direction) at the right edge of the second substrate 2 shown in FIG. 1. FIG. 3 shows the condition in which m scanning lines 11 are connected to the output terminal side of the gate driver 13. For this reason, for convenience in illustration, the scanning lines 11 are distinguished by the reference symbols G1 to Gm.

Also, switching elements T1, such as thin-film transistors (TFTs) elements, are disposed between each scanning line 11 and the pixel electrode 10 that is in the proximity thereof. The gate G of each switching element T1 is connected to a scanning line 11, and the drain D of each switching element T1 is connected to a pixel electrode 10.

The reference signal lines 12, as shown in FIG. 1, are formed along the row direction so as to pass in the vicinity of each pixel electrode 10 in parallel with the scanning lines 11, and each thereof is connected to the source S of a switching element T1 in the vicinity of each pixel electrode 10. Also, each of the reference signal lines 12 is collected in common to an extended interconnect 16 formed at the left edge part of the second substrate 2. This extended interconnect 16 is formed so as to extend in the column direction at the left edge part of the second substrate 2, and to extend up to the corner parts of the left edge part of the second substrate 2.

A drive IC 25 for driving the display device A is connected by terminals to the first substrate side terminal collection part 5 of the first substrate 1. The drive IC 25 supplies data signals to the plurality of data electrodes 3 on the first substrate 1 side. A non-illustrated drive IC is provided also on the second substrate 2 side, this outputting a selection command to the gate driver 13 regarding which scanning line 11 to select, to enable the application of a reference signal voltage to the reference signal line 12 at the target position.

The drive IC 15 connected to the first substrate side terminal collection part 5 and the drive IC provided on the second substrate 2 side may be separate ICs, or may be compound drive modules, in which a drive IC and other electronic parts are mounted onto an FPC board or the like. For this reason, although the detailed constitution of the IC 25 and the drive IC are not restricted in the present embodiment, it is sufficient, in any case, that they have the functionality required to drive the display device A. The drive IC may be provided separately on each of the first substrate 1 side and the second substrate 2 side, or on one or the other of the substrates, and may also be provided between the first substrate 1 and the second substrate 2 by wiring interconnection using a conductive material or the like.

In the display device A of the present embodiment, if the constitution is for a color display, a color filter with an RGB arrangement is usually disposed between the first substrate 1 and the data electrodes 3. In this present embodiment, however, the description of the color filter is omitted. Also, in recent years, liquid crystal display device have been provided using color filter on-array technology, in which a color filer is provided on the second substrate 2 side. For this reason, a structure can be adopted in which a color filter is provided on the second substrate 2.

A specific example of the constitution of a thin-film transistor as a switching element formed on the second substrate 2 side in the display device A having the above-described constitution will now be described.

FIG. 6A shows the plan view constitution of the switching element (thin-film transistor) T1 of the first example. In the switching element T1, source electrodes 21 and drain electrodes 20 are disposed on an insulating second substrate 2, made of glass or the like, with a prescribed spacing. In the switching element T1, an oxide semiconductor layer 22 is formed in a stripe shape so as to partially cover the source electrode 21 and the drain electrode 20, and a gate electrode 11a is formed over an insulating film 23 provided so as to cover the oxide semiconductor layer 22. The source electrode 21 constitutes the source S shown in FIG. 1. The drain electrode 20 constitutes the drain D shown in FIG. 1. The gate electrode 11a constitutes the gate G shown in FIG. 1.

In this example, both the reference signal lines 12 and the pixel electrodes 10 formed on the second substrate 2 are made from one transparent electrically conductive material that is a reduced transparent material from among such as ITO (indium tin oxide), IZO (indium zinc oxide), IGO (indium gallium oxide), or IGZO (indium gallium zinc oxide). Although the pixel electrode 10 is formed so that its overall shape is rectangular, a part thereof is formed as the drain electrode 20 that is formed to extend in a stripe shape in the column direction (Y direction) in the second substrate 2.

The reference signal lines 12, as described based on FIG. 1, extend in the row direction (X direction) over the second substrate 2. Additionally, parts of the reference signal lines 12 are formed so as to extend outward as connecting lines 12, passing by the side part of the individual pixel electrodes 10A. The end part of this connecting line 12 is formed as a source electrode 21 in the shape of a hook that wraps around the end part of the drain electrode 20 in proximity to the drain electrode 20. In FIG. 6A only two sets of structures that are combinations of the pixel electrode 10 and the connecting line 12, source electrode 21, and drain electrode 20 disposed therearound are shown. As shown in FIG. 1, however, this combination structure is formed over the second substrate 2, the number thereof being the same as the number of the pixel electrodes 10 disposed in a matrix arrangement on the second substrate 2.

A stripe-shaped oxide semiconductor layer 22 is laminated over the second substrate 2, and extends with a prescribed length in the X direction so as to cover the part of the drain electrode 20 and the source electrode 21 and to pass over the drain electrode 20 and the source electrode 21. A metal interconnect scanning line 11 that is a metal interconnection made of a metal material such as Al is formed over the oxide semiconductor layer 22, with an intervening insulating film 23. The insulating layer 23 used in this case may be an insulating layer made of SiO₂/SiNₓ layer or the like. However, it is alternatively possible, of course, to use the other insulating film (Si O₂/SiNₓ) used as an interlayer insulating film in the display device.

The oxide semiconductor layer 22 used in the above-described structure is made of IGZO. The IGZO is an amorphous oxide semiconductor film based on In—Ga—Zn—O and having a composition formula of InGaZnOₓ.

In the above-noted constitution, a part of the oxide semiconductor layer 22 is interposed between the source electrode 21 and the drain electrode 20. By doing this, the interposing part serves as a channel generating part 22a, a part of the scanning line 11 being disposed over the channel generating part 22a, with the insulating film 23 interposing therebetween, this part becoming the gate electrode 11a, so as to constitute the staggered switching element T1.

In FIG. 7, the reference symbol 19 is a backlight that has a light-emitting diode (LED) 18. The required number of light-emitting diodes 18, along with a light-guiding plate, is provided in the display device A. In FIG. 7, however, as a simplification, the light-guiding plate is not illustrated, and only one light-emitting diode 18 is shown.

In the display device A of the present embodiment, data signals are input to a plurality of data electrodes 3 of the first substrate 1 from the drive IC 15 connected to the first substrate terminal collection part 5, thereby driving the gate driver 13, and selecting the scanning line 11. Also, simultaneous with turning the required switching element T1 to the on state, the drive IC on the second substrate side applies a reference signal voltage (common voltage) from the reference signal line 12 to the pixel electrode 10 connected to the switching element T1. By doing this, the orientation of liquid crystal molecules of the liquid crystal layer existing at the intersecting regions between the data lines 3, to which signals are input, and the pixel electrodes 10, to which the reference signal voltage is applied, is controlled, thereby controlling the transmissivity to light. Alternatively, if an organic EL material layer interposes at the intersecting regions, the light emission of the organic EL material is controlled. By doing this, it is possible to obtain the desired video or the like.

In the switching element T1 of this example, an oxide semiconductor layer 22 made of IGZO or the like is formed over the second substrate 2, and a source electrode 21 of transparent electrically conductive material and a drain electrode 20 are provided below the oxide semiconductor layer 22. Alternatively, the second substrate 2 exists directly below the oxide semiconductor layer 22. Thus, in a liquid crystal display device having a display device with a backlight 19, the light from the backlight 19 is received from the rear surface side of the second substrate 2. In the case of an IGZO oxide semiconductor layer 22, however, the problem of light leakage current occurring can be avoided.

That is, if the backlight 19 has a light-emitting diode 18 as described above, it is possible, for the following reason, by using an oxide semiconductor layer 22, to suppress the occurrence of leakage current.

Although IGZO is a transparent substance, it absorbs light of short wavelengths (below approximately 420 nm), so that there is the risk of affecting its characteristics as a semiconductor. Assuming the backlight 19 is a cold cathode tube, the mercury UV light will be waveform-converted by the phosphor. However, because it is not easy to remove UV light, and because light emission from the blue phosphor provided in a cold cathode tube contains wavelengths 420 nm and lower, a problem tends to arise. For this reason, when a cold cathode tube backlight is used, some blocking means, such as a light-block layer, is required. With regard to this point, when the backlight 19 having the light-emitting diode 18 as a light source is used, it is possible to constitute a backlight 19 that emits almost no light of 420 nm or below. It is thus possible to avoid the problem of leakage current occurring in an oxide semiconductor layer 22 made of IGZO.

With regard to this point, in the case of a semiconductor layer made of a-Si or the like, in order to prevent light leakage current, a separate photolithography process step must be added to provide a light-blocking layer over the second substrate 2, so that the number of process steps increases commensurately. In contrast to this, when an oxide semiconductor layer 22 made of IGZO is used, the problem of light leakage can be avoided, as described above. For this reason, to the extent that it is not necessary to provide a light-blocking layer, it is possible to simplify the photolithography process steps.

In the above-described constitution, as shown in FIG. 6B, the terminal part 12b of the reference signal line 12 can be formed of a transparent electrically conductive material, such as ITO, and the terminal part 11b of the scanning line 11 can be formed of a metal material such as Al.

To manufacture an array substrate having switching elements T1 with the above-described constitution, a transparent electrically conductive film of ITO or the like is deposited onto an insulating second substrate 2. After that, a first photolithography process step of resist coating, exposure, developing, wet etching, and resist peeling is performed. By doing this, the pixel electrode 10A, the drain electrode 20, the source electrode 21, the connecting wire 12, and the reference signal line 12 that are in the form of thin films made of a transparent electrically conductive film shown in FIG. 6A and FIG. 6B are formed. Therefore, the pixel electrode 10A, the drain electrode 20, the source electrode 21, the connecting line 12, and the reference signal line 12 are deposited at the same time and made of the same material (the above-described transparent electrically conductive material).

Next, after the above-described process step, an oxide semiconductor layer made of IGZO is deposited using sputtering. Then, the insulating film 23 with a laminated structure of SiO₂/SiNₓ is deposited using CVD. Then, the scanning line 11 with a laminated structure of Al/Mo and the gate electrode 11a are deposited using sputtering. Then, a second photolithography process step that performs resist coating, exposure, developing, etching of the Al/Mo using wet etching, etching of the SiO₂/SiNₓ using dry etching, and etching of the IGZO oxide semiconductor layer using wet etching is performed. By doing this, the switching elements T1 having the structure shown in FIG. 6A, FIG. 6B, and FIG. 7 can be formed on the second substrate 2.

In the manufacturing in the present embodiment, for example, a laminated structure with a film thickness of approximately 300 nm is applied as a scanning line 11 and gate electrode 11a having a laminated structure of Al/Mo. An insulating film 23 having a film thickness of approximately 400 nm is applied as the SiO₂/SiNₓ layer for the gate. An IGZO oxide semiconductor layer 22 having a film thickness of approximately 100 nm is applied. By doing this, it is possible to form a pixel electrode 10A made of ITO and having a film thickness of approximately 80 nm or 100 nm, a drain electrode 20, a source electrode 21, and a reference signal line 12.

After making the cells, a polarizer is adhered, a source driver is mounted, and the gate driver 13 is provided on the second substrate 2. By doing this, it is possible to obtain a TFT array substrate for a display device.

In the above-described method for manufacturing, in contrast to the pixel electrode 10A, the drain electrode 20, the source electrode 21, the connecting line 12, and the reference signal line 12 that are made of the same material by simultaneous deposition, for example, a transparent electrically conductive materials such as ITO, it is necessary to etch the oxide semiconductor layer 22 that is made of IGZO. Selective etching of a transparent electrically conductive material/IGZO, such as ITO, can be done by using an etchant that contains any one of acetic acid, an organic acid (citric acid), hydrochloric acid, and perchloric acid.

That is, in a thin-film semiconductor that contains two or more types of oxides selected from IGZO, IZO, IGO, and ITO, by using an acid as described above, it is possible to perform wet etching with precision and high selectivity.

For the above-described acetic acid, the undiluted solution of a commercially available acetic acid liquid may be used as is, or an undiluted solution may be diluted with pure water up to four times the volume. To maintain a high IZO:IGZO etching selectivity ratio, it is more desirable to dilute the undiluted solution with pure water from 0.5 to 2 times the volume. The etching process step using the above-described acetic acid can be performed by immersion in an aqueous solution of acetic acid.

The organic acid is not limited to being citric acid, and can be a generally known organic acid, such as malonic acid, malic acid, tartaric acid, oxalic acid, formic acid, glycolic acid, or maleic acid. Under special conditions, a ligand of the organic acid, for example, COO⁻ bonds with In, forms a complex ion and dissolves. In the following the description is for the case of using citric acid. The above-described citric acid, is a solution in which commercially available citric acid (citric acid•1 hydrate, chemical formula C₃H₄(OH)(COOH)₃.H₂O, white solid crystals) is completely dissolved in pure water.

For the above-described hydrochloric acid, the undiluted solution of a commercially available concentrated hydrochloric acid may be used as is, or an undiluted solution may be diluted with pure water up to 60 times the volume.

To maintain a high and stable etching selectivity ratio of an indium oxide, such as IZO, IGZO, or IGO, with respect to ITO, it is preferable that the hydrochloric acid concentration of an etchant containing hydrochloric acid be made by diluting the undiluted solution with pure water from 4 to 60 times the volume.

For the above-described perchloric acid, the undiluted solution of a commercially available concentrated perchloric acid solution may be used as is, or the undiluted solution may be made by diluting undiluted solution with pure water up to 20 times the volume. In an etchant containing perchloric acid, the preferred concentration of perchloric acid can be made by diluting the undiluted solution with pure water from 1 to 20 times the volume.

By using the etchants described above, it is possible to make etching rates of indium oxides in the sequence of IZO, IGZO, IGO, ITO.

It is known that, with any one of the above-described acid etchants, that is, acetic acid, organic acid, hydrochloric acid, and perchloric acid, it is not possible to each the usually used gate insulating film, for example, a silicon nitride film. Additionally, even if, for example, silicon oxide or a dielectric material, such as silicon oxynitride, HfO₂. HfAlO, HfSiON, Y₂O₃ is used in place of silicon nitride film as the gate insulating film, because these are also not etched by the above-described acid etchants, it is possible to apply them to the above-described switching element T1.

Of these acids, using acetic acid for example, it is possible to control so that the etching rate difference of ITO in units of nm/minute is three orders of magnitude different from that of IZO, IGZO, and IGO. For example, with an etching rate of 0.5 to 10 nm/minute for IZO, IGZO, and IGO, because it is possible to control the etching rate of ITO to 0.05 to 0.06 nm/minute, it is possible to perform etching with preferable selective ratio. Also, with citric acid or perchloric acid as well, it is possible to perform etching processing that achieves the same type of etching rate difference.

According to the above-described manufacturing method, it is possible to form the switching element T1 on the second substrate 2 with three deposition process steps using sputtering, one deposition process step using CVD, two photolithography process steps, one dry etching process step, and one wet etching process step.

That is, in the above-described manufacturing method, it is possible to manufacturing the switching element T1 with one deposition process step using CVD and two photolithography process steps. Therefore, compared with the conventional art, in which four to five photolithography process steps and two deposition steps using CVD were required, it is possible to achieve a reduction in the number of process steps. It is therefore possible to reduce the cost of manufacturing a thin-film transistor array substrate for a display device.

In the switching element T1 of the above-described constitution, the pixel electrode 10A, the drain electrode 20, the source electrode 21, the connecting line 12, and the reference signal line 12 were formed of ITO, these may be constituted by a material obtained by hydrogen reduction of IGZO to make it a conductor. If these elements are formed by IGZO, the oxide semiconductor layer 22 can also be formed from IGZO. For this reason, the elimination of the process to deposit ITO and the ability to share the process of depositing IGZO enable a further advance in the reduction of process steps.

### <Second Example of the Switching Element>

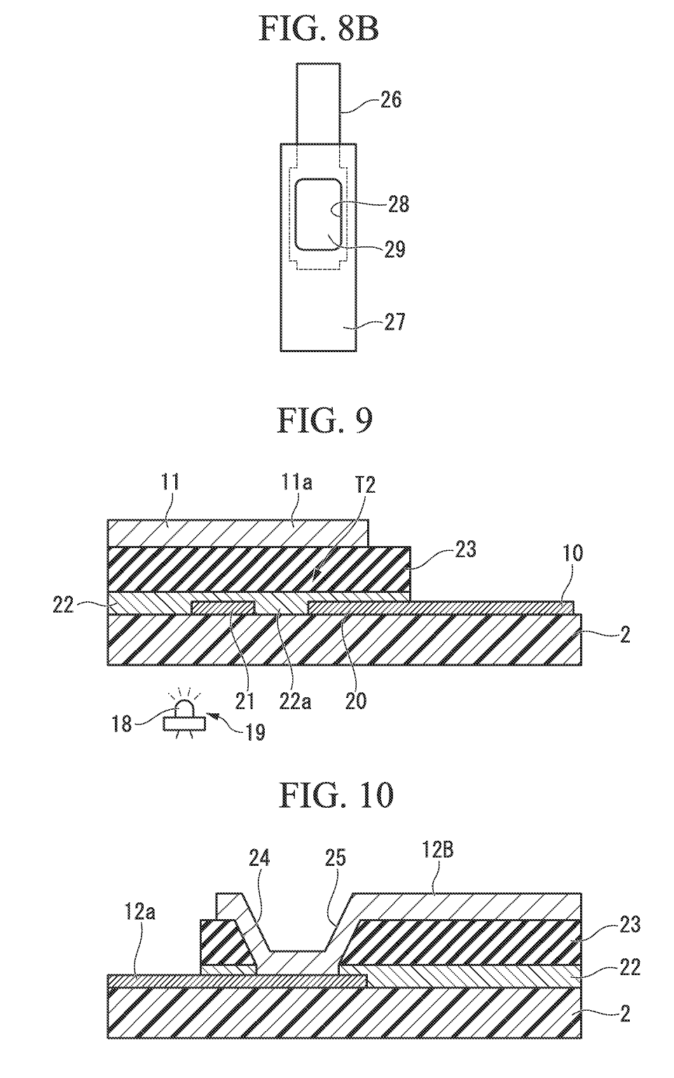

FIG. 8A to FIG. 10 are drawings showing the second example of a switching element applied to an array substrate according to the present invention. The switching element T2 of the second example is an example having a different reference signal line part from that of the switching element T1 of the first example. The other structural parts thereof are the same as in the structure of the above-described first example.

FIG. 8A is a plan structure of the switching element (thin-film transistor) T2 of the second embodiment. In the switching element T2 of the second embodiment, the pixel electrodes 10A formed on the second substrate 2 that is made of an insulator such as glass are all made of a transparent electrically conductive material, the same as in the above-described first embodiment. Although the pixel electrode 10A is formed so that its overall shape is rectangular, a part thereof is formed as the drain electrode 20 that is formed to extend outwardly in a stripe shape.

The reference signal lines 12B, as described based on FIG. 1, extend in the row direction (X direction) over the second substrate 2. Additionally, parts of the reference signal lines 12B are formed so as to extend outward as connecting lines 12a, passing by the side part of the individual pixel electrodes 10. Edge side of this connecting line 12a is formed as a source electrode 21 in the shape of a hook that wraps around the end part of the drain electrode 20 in the vicinity of the drain electrode 20. In the second embodiment, however, the part of the reference signal line 12B that extends in the row direction (X direction) is formed on the insulating film 213 as a metal interconnect made of a metal material such as aluminum. The part of the connection line 12a, similar to the structure of the first embodiment, is constituted by a transparent electrically conductive material on the second substrate 2.

Therefore, as shown in FIG. 10, the reference signal line 12B and the connecting line 12a are electrically connected by a conductive part 25 that occupies a part of the contact hole 24 formed so as to pass through the oxide semiconductor layer 22 and the insulating film 23.

A stripe-shaped oxide semiconductor layer 22 extending in the X direction so as to pass over the drain electrode 20 and the source electrode 21 and cover a part of the drain electrode 20 and the source electrode 21 is laminated over the second substrate 2. Then, a scanning line 11 that is a metal interconnect made of a metal material such as Al is formed on the oxide semiconductor layer 22, with an insulating film 23 interposed therebetween. This structure is the same as the above-described structure of the first embodiment.

In the above structure, by the interposing of a part of the oxide semiconductor layer 22 between the source electrode 21 and the drain electrode 20, the interposing part is made the channel generating part 22a. A part of the scanning line 11 is disposed over the channel generating part 22a, with the insulating film 23 interposed therebetween, this part becoming the gate electrode 11, so as to constitute the switching element T2. This point is the same as in the above-described embodiment.

In the switching element T2 of the second example, the same effect can be achieved as with the switching element T1 of the above-described embodiment. In the switching element T2 of the second embodiment, the point of difference with respect to the above-described first embodiment is the point of the reference signal line 12B being made a metal interconnect. For this reason, it is possible to make the reference signal line 12B a low-resistance interconnect. Therefore, even the reference signal line 12B becomes long when applied to a large display device, it is difficult for problems such as signal delay caused by increased interconnect resistance to occur, and achieving the characteristic that application to a large display device is possible without a problem.

In the above-described constitution, as shown in FIG. 8B in order to connect the layer 26 made of a transparent electrically conductive material, such as ITO, and the terminal 27, a contact hole 28 is formed in the insulating film 23 and a conductive part 29 is formed. By doing this, conduction is made between the layers above and below via the interposed insulating film 23.

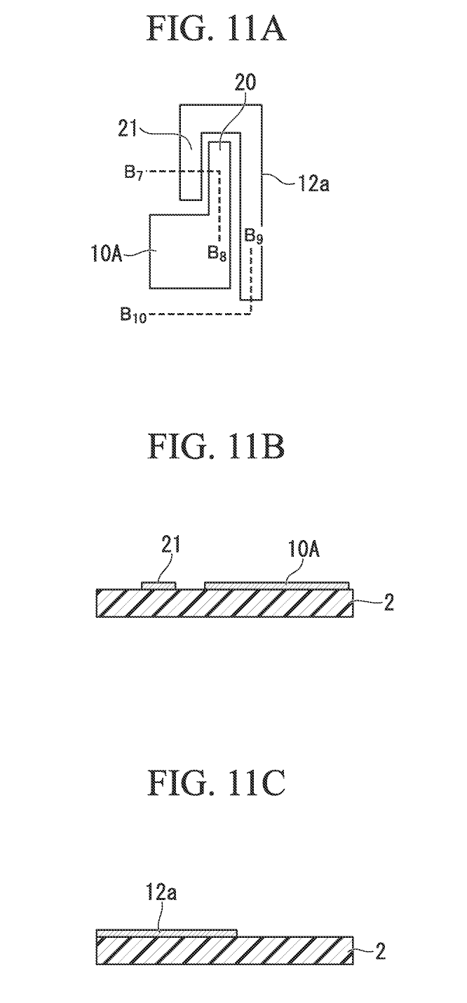

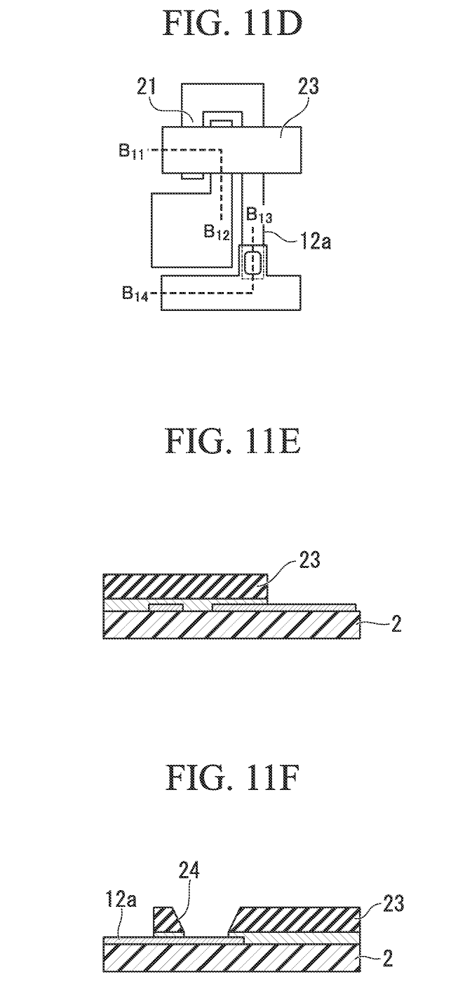

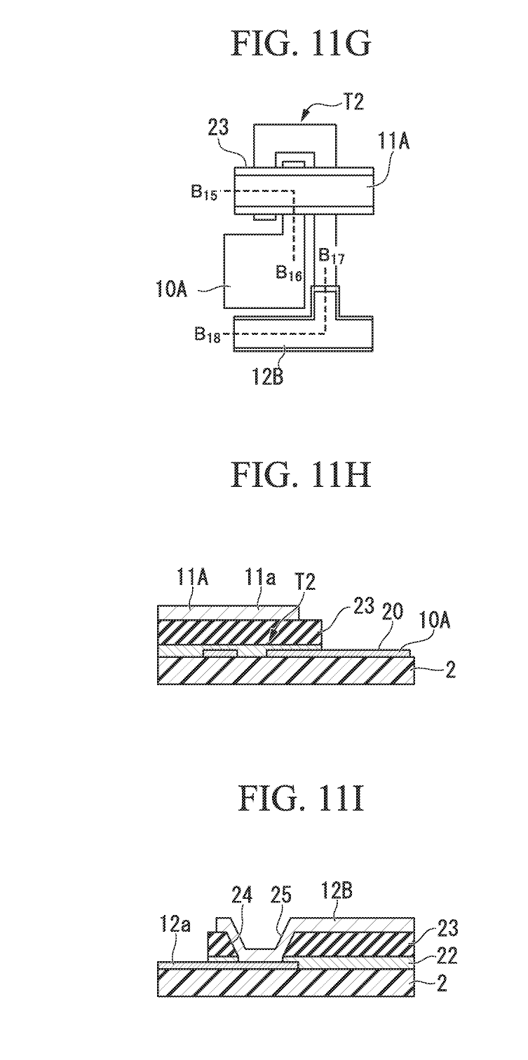

To manufacture the switching element T2 with the above-described constitution, a transparent electrically conductive film of ITO is deposited onto the second substrate 2 that is an insulator. After that, a first photolithography process step of resist coating, exposure, developing, wet etching, and resist peeling is performed. By doing this, the pixel electrode 10A made of transparent electrically conductive film having the plan view shape shown in FIG. 11A, the drain electrode 20, the source electrode 21, and the connecting wire 12 are formed. Therefore, the pixel electrode 10A, the drain electrode 20, the source electrode 21, and the connecting line 12 are deposited at the same time and made of the same material.

Next, after the above-described process step, as shown in FIG. 11D, an oxide semiconductor layer made of IGZO is deposited using sputtering. Then, an insulating film 23 with a laminated structure of SiO₂/SiNₓ is deposited using CVD. Then, a second photolithography process step that performs resist coating, exposure, developing, etching of the SiO₂/SiNₓ layer using dry etching, and etching of the IGZO oxide semiconductor layer using wet etching is performed, thereby forming the contact hole 24. Next, as shown in FIG. 11G, the scanning line 11 having a laminated structure of Al/Mo and a gate electrode 11a are deposited using sputtering. Then, resist coating, exposure, developing, and wet etching are done to etch the Al/Mo layer. By doing this, a switching element T2 having the structure shown in FIG. 8A, FIG. 8B, FIG. 9, and FIG. 10 can be made on the second substrate 2. Additionally, by providing the gate driver 13, it is possible to obtain the TFT array substrate.

According to the above-described second manufacturing method, it is possible to form the switching element T2 on the second substrate 2 with three deposition process steps using sputtering, one deposition process step using CVD, three photolithography process steps, one dry etching process step, and three wet etching process step.

That is, in the above-described manufacturing method, it is possible to manufacturing the switching element T2 with one deposition process step using CVD and three photolithography process steps. For this reason, compared with the conventional art, in which four to five photolithography process steps and two deposition steps using CVD were required, it is possible to achieve a reduction in the number of process steps. It is therefore possible to reduce the cost of manufacturing a thin-film transistor array substrate for a display device.

### <Third Example of the Switching Element>

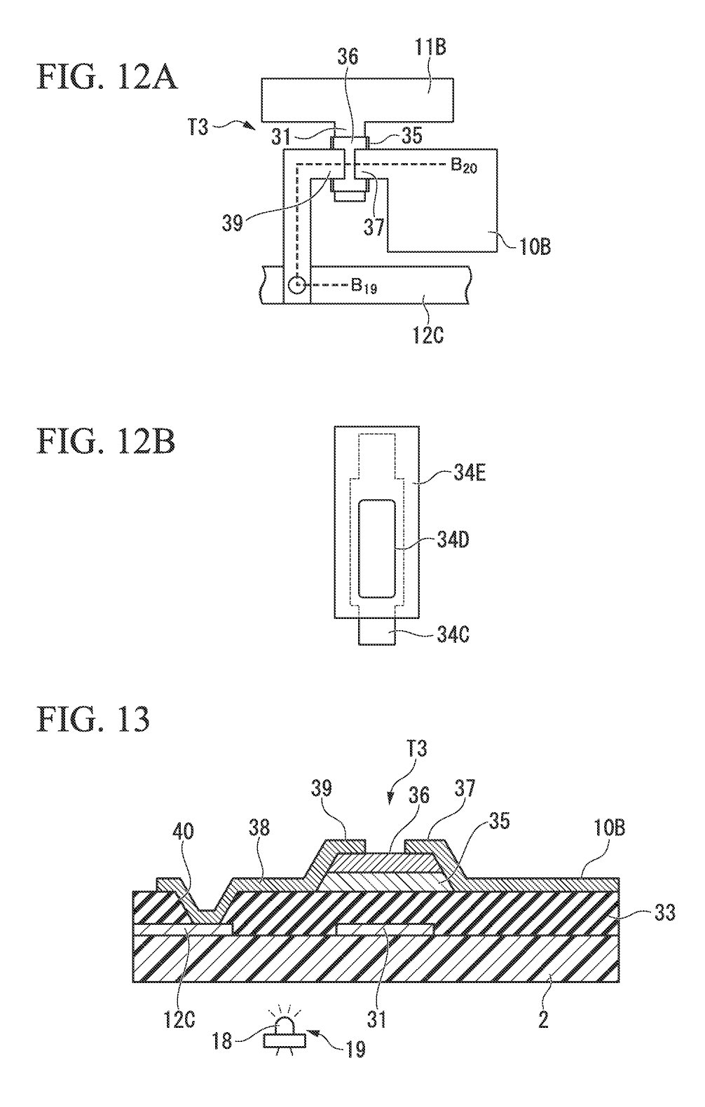

FIG. 12A, FIG. 12B, and FIG. 13 are drawings showing the third example of a switching element T3 according to the present invention. The switching element T3 of this example, in contrast to the switching elements T1 and T2 described above, is an example in which the TFT part is made a reverse-staggered structure, with both the scanning lines and the reference signal lines made of a metal material.

FIG. 12A is a plan structure of the switching element (thin-film transistor) T3 of the third example. In the switching element T3 of the third example, the reference signal line 12C and the scanning line 11B that are formed over the insulating second substrate 2, as described based on FIG. 1, extend in the row direction (X direction). The reference line 12C and the scanning line 11B are made as metal interconnects made of a metal material such as Al.

In the pixel electrode of the vicinity of each scanning line 11B, a gate electrode 31 with the shape of a gravestone when seen in plan view is formed. An insulating film 33 is formed that covers the reference signal line 12C and the scanning line 11B. An oxide semiconductor layer 35 and a channel-protection layer 36 that are island shapes are laminated over the insulating film 33 and above the gate electrode 31. A pixel electrode 10B made of a transparent electrically conductive film such as ITO is formed over the insulating film 33. A drain electrode 37 that extends outward from the pixel electrode 10B is formed so as to cover the end part on one side of the oxide semiconductor layer 35 and the channel-protection layer 36. From one part of the reference signal line 12C positioned in the vicinity of the pixel electrode 10B up to a position near the gate electrode 31, a connecting line 38 that extends outwardly along and above the insulating film 33 is formed. One end of the connecting part 38 is formed so as to cover the end part on the other side of the oxide semiconductor layer 35 and the channel-protection layer 36, and a source electrode 39 is formed. The end part of the connecting part 38 at the reference signal line 12C side is connected to the reference signal line 12C via a contact hole 40 formed in the insulating film 33.

In the above-noted constitution, an oxide semiconductor layer 35 is interposed between the source electrode 39 and the drain electrode 37, and by the gate electrode 31 being disposed below the oxide semiconductor layer 35, the reverse-staggered switching element T3 is formed.

FIG. 12B is a drawing showing the constitution of the terminal part of the interconnect part. The terminal part 34C is covered by an insulating film. A terminal part conductor 34E made of a transparent electrically conductive material such as ITO is connected via a contact hole 34D formed in the insulating film.

By using the switching element T3 of the present embodiment, it is possible to make the reference signal line 12C and the scanning line 11B metal interconnects made of a metal material, thereby achieving low resistance. For this reason, similar to the case of the above-described second embodiment, it is possible to achieve the effect of application even a large liquid crystal display device. Also, if the structure of the switching element T3 of the present embodiment is used, the disposition of a diode as a static electricity countermeasure in the area surrounding the second substrate 2 is facilitated. Also, because of the reverse-staggered structure, there is a good match to existing manufacturing facilities for general liquid crystal display devices, thereby achieving the characteristic of ease of manufacturing.

Additionally, as shown in FIG. 13, if the backlight 19 is a light-emitting diode 18 of the constitution described above, by using an oxide semiconductor layer 22, it is possible to make the occurrence of leakage current, particularly in the visible-light region, small.

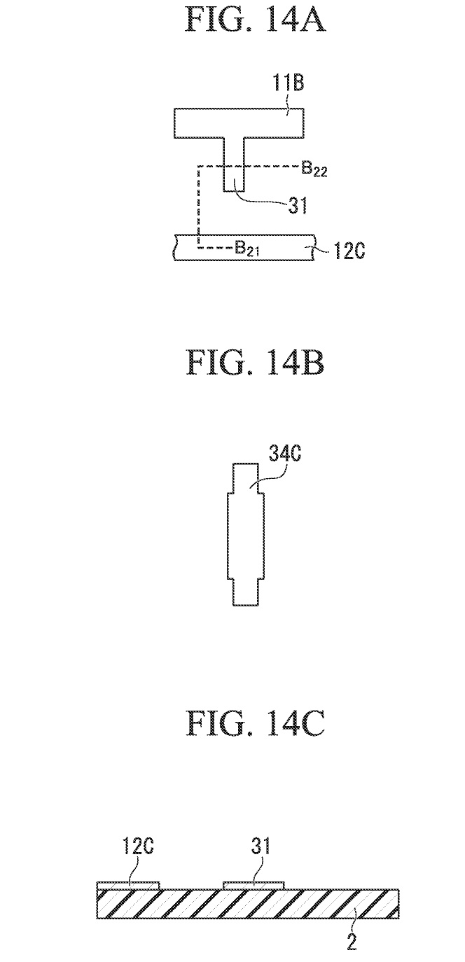

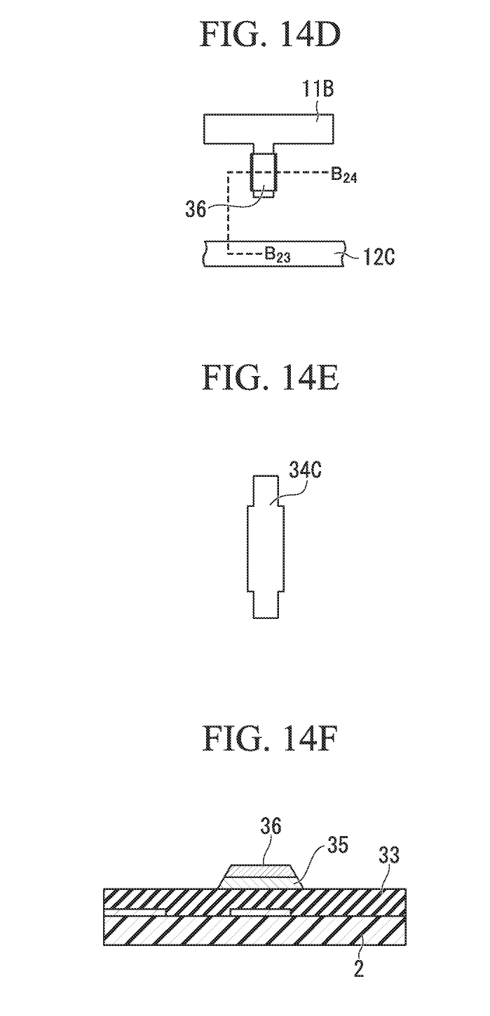

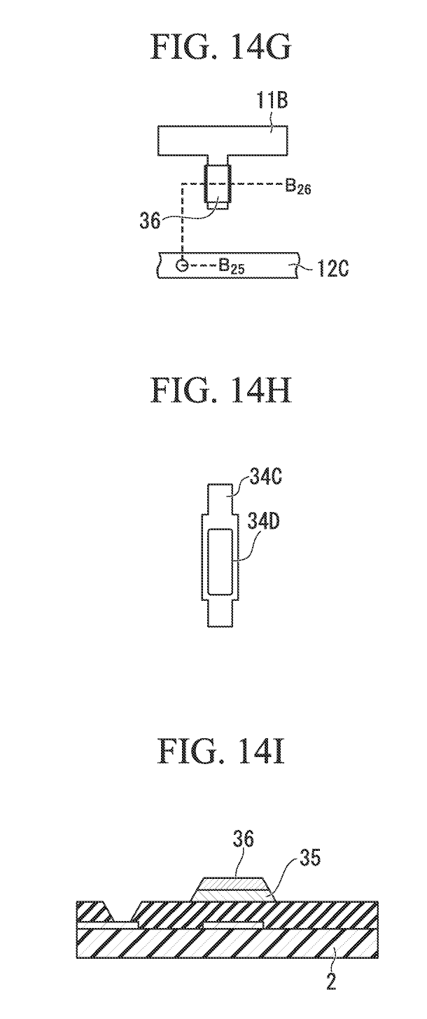

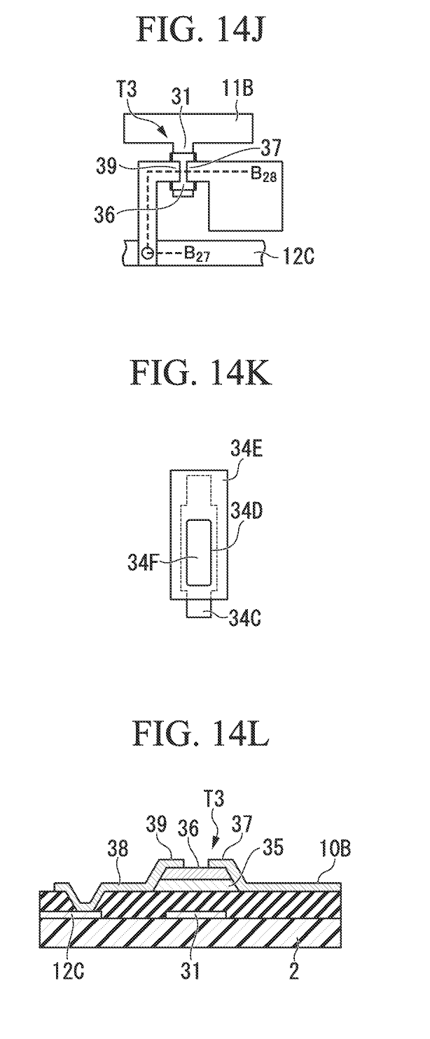

To manufacture the switching element T3 with the above-described constitution, as shown in FIG. 14A and FIG. 14C, a laminated film of Al/Mo is formed over the insulating second substrate 2. Then, a first photolithography process step of resist coating, exposure, developing, wet etching, and resist peeling is performed to etch the Al/Mo layer. By doing this, the scanning line 11B having the gate electrode 31, and the terminal part 34C that will be connected to the reference signal line 12C and to the terminals of required interconnects are formed.

Next, as shown in FIG. 14D and FIG. 14F, CVD is used to deposit the insulating film 33 having a laminated structure of a SiO₂/SiNₓ film. Then, sputtering is done to deposit an IGZO oxide semiconductor layer and a protective film. Then, a second photolithography process step of resist coating, exposure, developing, wet etching, and resist peeling is done, as shown in FIG. 14D and FIG. 14F. Next, as shown in FIG. 14G and FIG. 14I, resist coating, exposure, developing, and dry etching are done to etch the SiO₂/SiNₓ layer, and a transparent electrically conductive film made of ITO is deposited. After that, a third photolithography process step of resist coating, exposure, developing, wet etching, and resist peeling is performed. By doing this, the pixel electrode 10B made of a transparent electrically conductive film and having the plan view shape shown in FIG. 14J, the drain electrode 37, the source electrode 39, and the connecting part 38 are formed. The contact hole 34D is formed in the insulating film 33 deposited over the terminal part 34C, enabling the constitution of a terminal by forming a terminal conductor 34E made of ITO.

By doing this, it is possible to fabricate a switching element T3 having the structure shown in FIG. 12A, FIG. 12B, and FIG. 13 on the second substrate 2, and to obtain a TFT array substrate by providing the gate driver 13.

According to the above-described third manufacturing method, it is possible to form the switching element T3 on the second substrate 2 by three deposition process steps using sputtering, one deposition step using CVD, four photolithography process steps, one dry etching process step, and three wet etching process steps. That is, according to the above-described manufacturing method, the n⁺a-Si layer of the conventional art is not required. For this reason, compared with the reverse-staggered type manufacturing method that has required the n⁺a-Si layer, it is possible to achieve the effect of reducing the masks used in photolithography process steps.

Also, although there are four photolithography process steps in the above process, so that there are four masks, by using half-tone exposure it is possible to combine the process steps shown in FIG. 14D and FIG. 14G, in which case it is possible to achieve a further reduction in the number of process steps.

### <Fourth Example of the Switching Element>

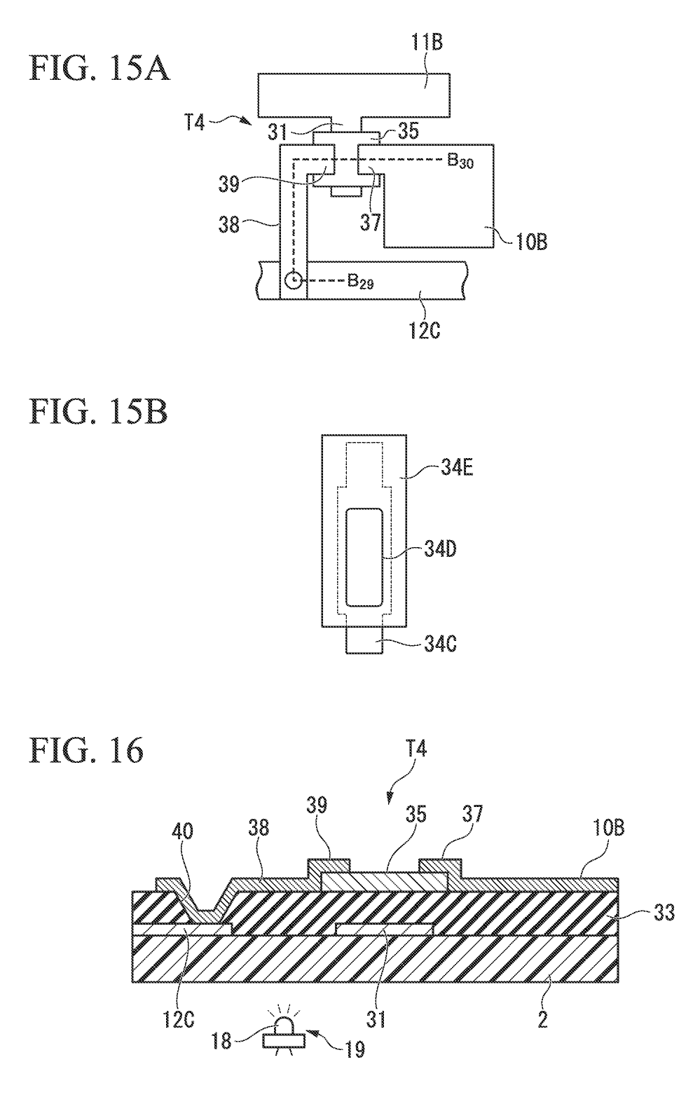

FIG. 15A, FIG. 15B, and FIG. 16 are drawings showing the fourth example of a switching element T4 according to the present invention. The switching element T4 of this example, in contrast to the switching element T3 described above, is an example having a reverse-staggered structure from which the channel-protection layer 36 is omitted.

FIG. 15A is a constitution plan view of the switching element (thin-film transistor) T4 of the fourth example. In the switching element T4 of the fourth example, the reference signal line 12C and the scanning line 11B that are formed over the insulating second substrate 2, as described based on FIG. 1, extend in the row direction (X direction). The reference line 12C and the scanning line 11B are made as metal interconnects made of a metal material such as Al.

In the pixel electrode vicinity of each scanning line 11B, a gate electrode 31 with the shape of a gravestone when seen in plan view is formed. An island-shaped oxide semiconductor layer 35 is laminated over the insulating film 33 and above the gate electrode 31. A pixel electrode 1013 made of a transparent electrically conductive film such as ITO is formed over the insulating film 33. A drain electrode 37 that extends outward from the pixel electrode 10B is formed so as to cover the end part on one side of the oxide semiconductor layer 35. From one part of the reference signal line 12C positioned in the vicinity of the pixel electrode 10B up to a position near the gate electrode 31 is formed a connecting line 38 that extends outwardly along and above the insulating film 33. One end of the connecting part 38 is formed so as to cover the end part on the other side of the oxide semiconductor layer 35, and a source electrode 39 is formed. The end part of the connecting part 38 at the reference signal line 12C side is connected to the reference signal line 12C via a contact hole 40 formed in the insulating film 33.

In the above-noted constitution, an oxide semiconductor layer 35 is interposed between the source electrode 39 and the drain electrode 37, and by the gate electrode 31 being disposed below the oxide semiconductor layer 35, the reverse-staggered switching element T4 is formed.

FIG. 15B is a drawing showing the constitution of the terminal part of the interconnect part. The terminal part 34C is covered by an insulating film. A terminal part conductor 34E made of a transparent electrically conductive material such as ITO is connected via a contact hole 34D formed in the insulating film.

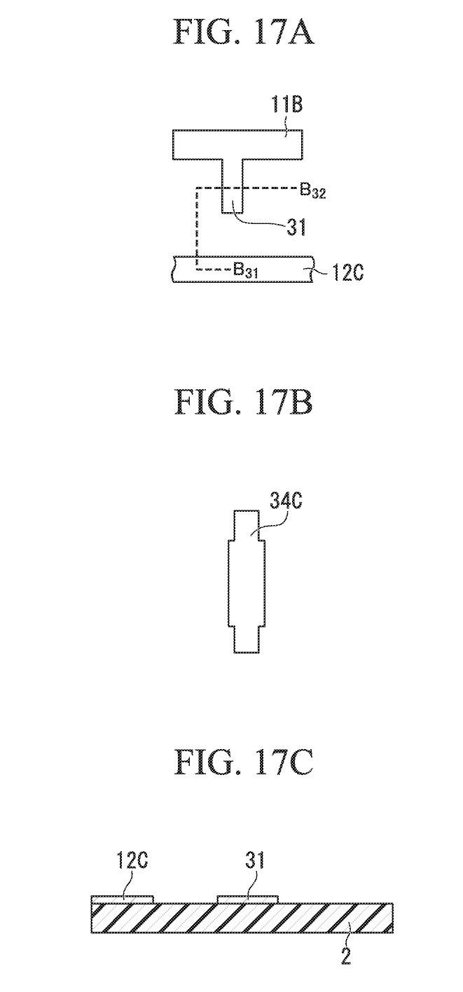

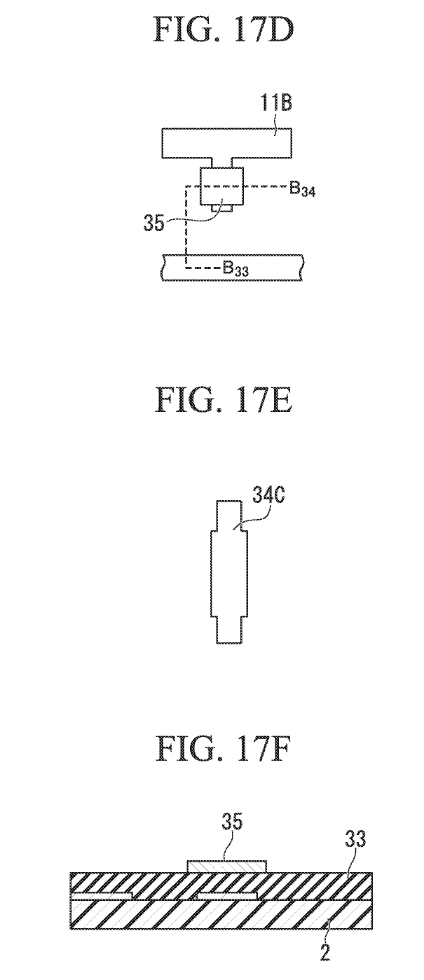

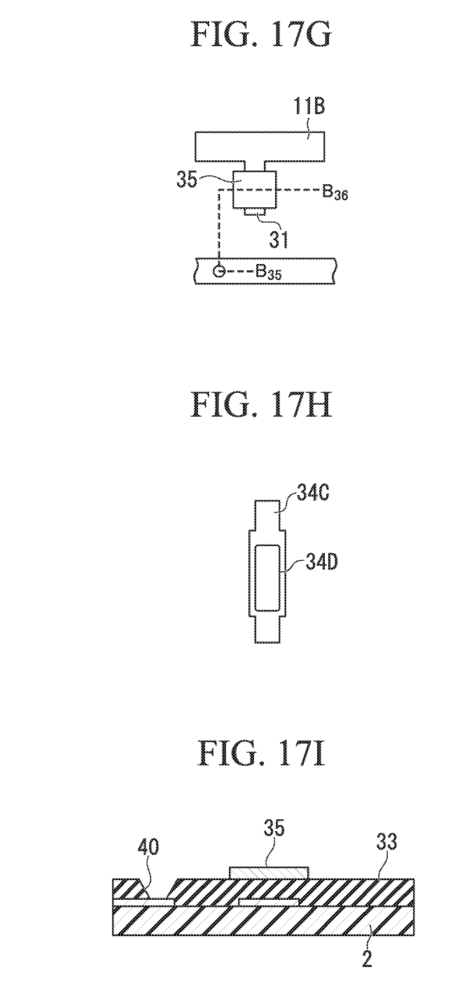

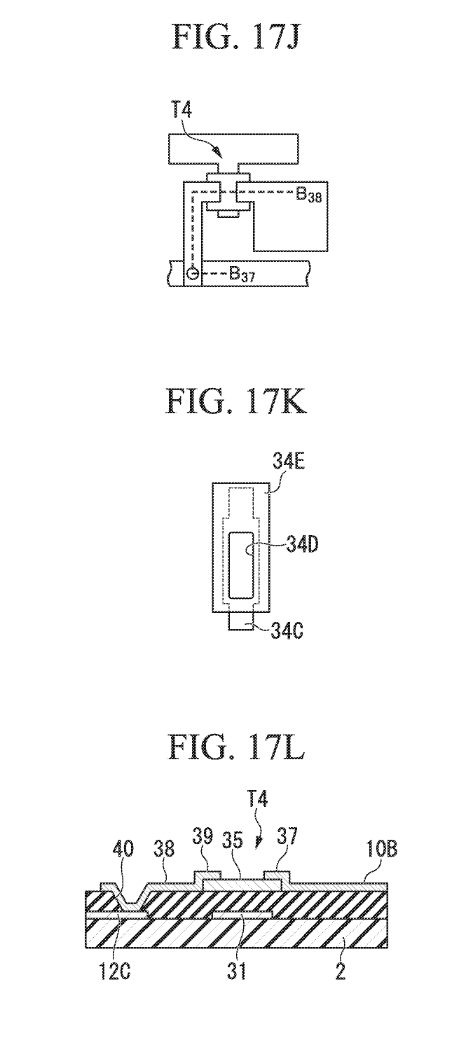

To manufacture the switching element T4 with the above-described constitution, as shown in FIG. 17A and FIG. 17C, a laminated film of Al/Mo is formed using sputtering over the insulating second substrate 2. Then, a first photolithography process step of resist coating, exposure, developing, wet etching, and resist peeling is performed to etch the Al/Mo layer. By doing this, the scanning line 11B having the gate electrode 31, and the reference signal line 12C are formed.

Next, as shown in FIG. 17D and FIG. 17F, CVD is used to deposit the insulating film 33 having a laminated structure of a SiO₂/SiNₓ film. Then, sputtering is done to deposit an IGZO oxide semiconductor layer. Then, a second photolithography process step of resist coating, exposure, developing, wet etching, and resist peeling is done, thereby obtaining the condition as shown in FIG. 17D and FIG. 17F. Next, resist coating, exposure, developing, and dry etching are done to etch the SiO₂/SiNₓ layer, thereby obtaining a condition as shown in FIG. 17G and FIG. 17I. Next, a transparent electrically conductive film made of ITO is deposited. After that, a third photolithography process step of resist coating, exposure, developing, wet etching, and resist peeling is performed. By doing this, the pixel electrode 10B the drain electrode 37, the source electrode 39, and the connecting part 38 that are made of a transparent electrically conductive film and having the plan view shape shown in FIGS. 17J and 17L are formed. The contact hole 34D is formed in the insulating film 33 deposited over the terminal part 34C, enabling the constitution of a terminal by forming a terminal conductor 34E made of ITO.

By doing this, it is possible to fabricate a switching element T4 having the structure shown in FIG. 15A, FIG. 15B, and FIG. 16 on the second substrate 2, and to obtain a TFT array substrate by providing the gate driver 13.

According to the above-described fourth manufacturing method, it is possible to form the switching element T4 on the second substrate 2 by three deposition process steps using sputtering, one deposition step using CVD, four photolithography process steps, two dry etching process step, and three wet etching process steps.

That is, according to the above-described manufacturing method, the n⁺a-Si layer of the conventional art is not required. For this reason, compared with the reverse-staggered type manufacturing method that has required the n⁺a-Si layer, it is possible to achieve the effect of reducing the masks used in photolithography process steps.

Also, although there are four photolithography process steps in the above process, so that there are four masks, by using half-tone exposure it is possible to combine the process steps shown in FIG. 17D and FIG. 17G, in which case it is possible to achieve a further reduction in the number of process steps.

### <Fifth Example of the Switching Element>

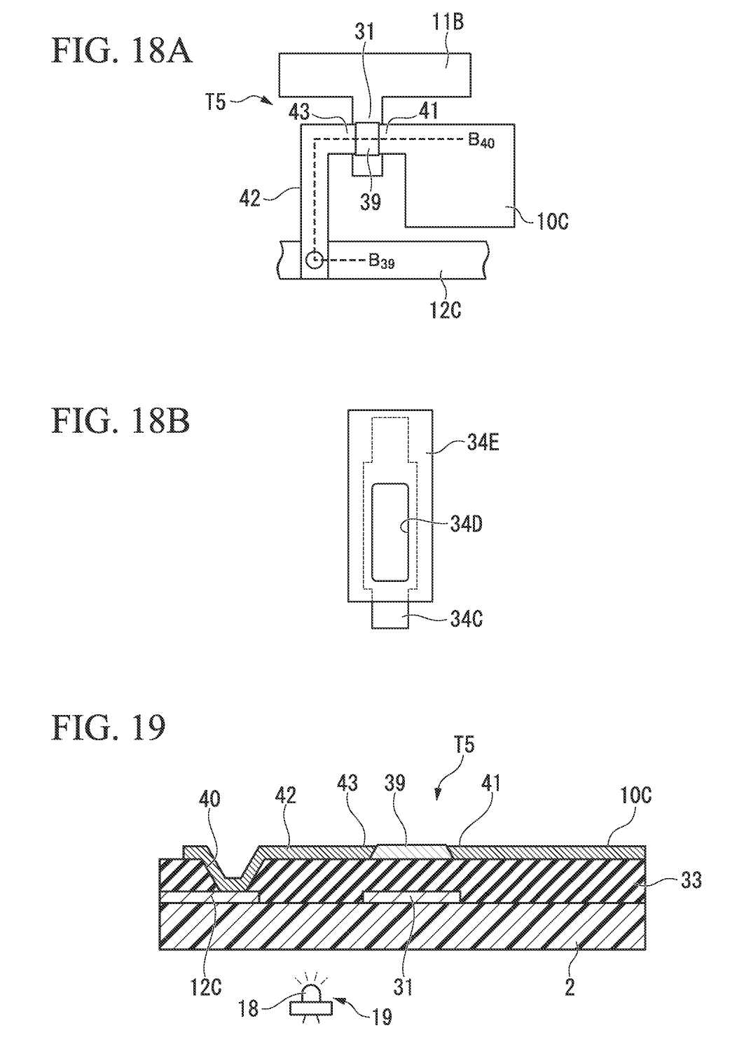

FIG. 18A, FIG. 18B, and FIG. 19 are drawings showing the fifth example of a switching element T5 according to the present invention. The switching element T5 of this example, in contrast to the switching element T4 described above, is an example having a reverse-staggered structure in which the pixel electrode, the drain electrode, the source electrode, and the connecting line are constituted from a reduced substance of an IGZO oxide semiconductor.

FIG. 18A is constitution plan view of the switching element (thin-film transistor) T5 of the fifth example. In the switching element T5 of the fifth example, the reference signal line 12C and the scanning line 11B that are formed over the insulating second substrate 2, as described based on FIG. 1, extend in the row direction (X direction). The reference line 12C and the scanning line 11B are made as metal interconnects made of a metal material such as Al.

In the pixel electrode vicinity of each scanning line 11B, a gate electrode 31 with the shape of a gravestone when seen in plan view is formed. An insulating film 33 is formed that covers the reference signal line 12C and the scanning line 11B. An IGZO oxide semiconductor layer 39 is laminated over the insulating film 33 and above the gate electrode 31.

Additionally, in this fifth example, a pixel electrode 10C made of an IGZO oxide semiconductor layer is formed. A drain electrode 41 that extends outward from the pixel electrode 10C is formed so as to be connected as one with the oxide semiconductor layer 39. From one part of the reference signal line 12C positioned in the vicinity of the pixel electrode 10C up to a position near the gate electrode 31, a connecting line 42 made of an IGZO oxide semiconductor layer extends outwardly above the insulating film 33. One end of the connecting part 42 is formed so as to been connected as one with the oxide semiconductor layer 40. The part that is connected as one with the oxide semiconductor layer 39 is made the source electrode 43. The oxide semiconductor layer 39, the pixel electrode 10C, the drain electrode 41, the source electrode 43, and the connecting line 42 are all made of IGZO. The oxide semiconductor layer 39 is provided as a semiconductor layer, and the pixel electrode 10C, the drain electrode 41, the source electrode 43, and the connecting line 42 are all made conductors by hydrogen plasma processing of IGZO to obtain a reduced substance.

The end part of the connecting line 42 at the reference signal line 12C is connected to the reference signal line 12C via a contact hole 40 that is formed in the insulating film 33.

In the above-noted constitution, an oxide semiconductor layer 39 is interposed between the source electrode 43 and the drain electrode 41, and by the gate electrode 31 being disposed below the oxide semiconductor layer 39, the reverse-staggered thin film transistor is formed.

FIG. 18B is a drawing showing the constitution of the terminal part of the interconnect part. The terminal part 34C is covered by an insulating film. A terminal part conductor 34E made of a reduced IGZO substance is connected via a contact hole 34D formed in the insulating film.

In the switching element T5 of the fifth example, the scanning line 11B and the reference signal line 12C are made metal interconnects. For this reason, it is possible to make the scanning line 11B and the reference signal line 12B low-resistance interconnects. Therefore, even the scanning line 11B and the reference signal line 12B become long when applied to a large display device, it is difficult for problems such as signal delay caused by increased interconnect resistance to occur, and achieving the characteristic that application to a large display device is possible without a problem. Additionally, if the backlight 19 is a light-emitting diode 18 of the constitution described above, by using an oxide semiconductor layer 22, it is possible to make the occurrence of leakage current, particularly in the visible-light region, small.

Also, if the constitution of the switching element T5 of the present embodiment is used, the disposition of a diode as a static electricity countermeasure in the area surrounding the second substrate 2 is facilitated. Also, because the basic structure is a reverse-staggered structure, there is a good match to existing manufacturing facilities for general liquid crystal display devices, thereby achieving the characteristic of ease of manufacturing.

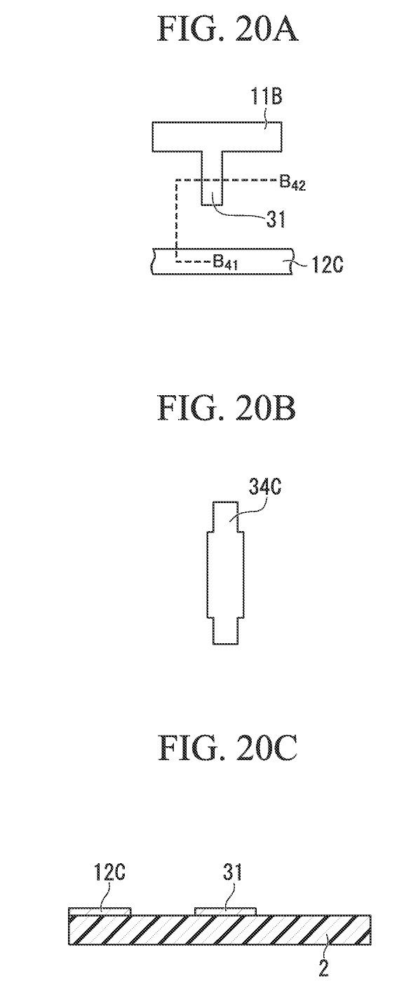

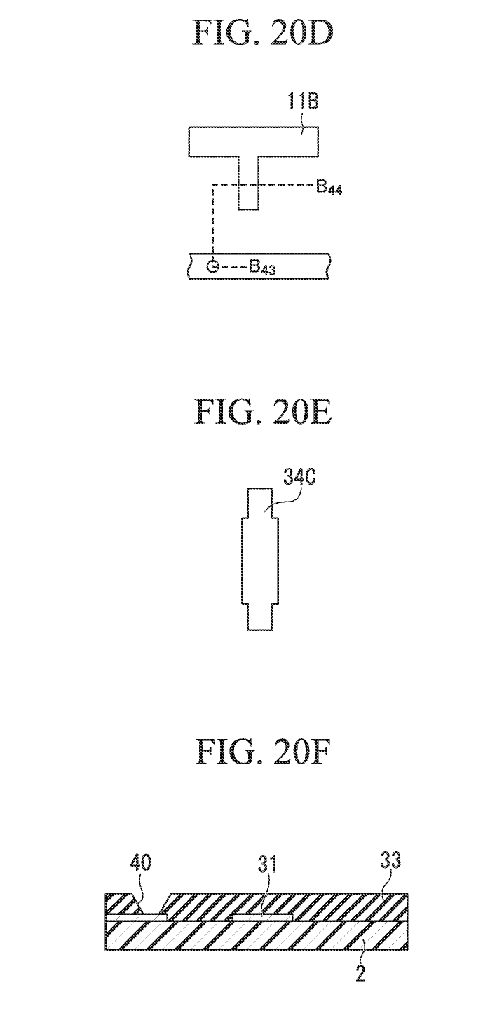

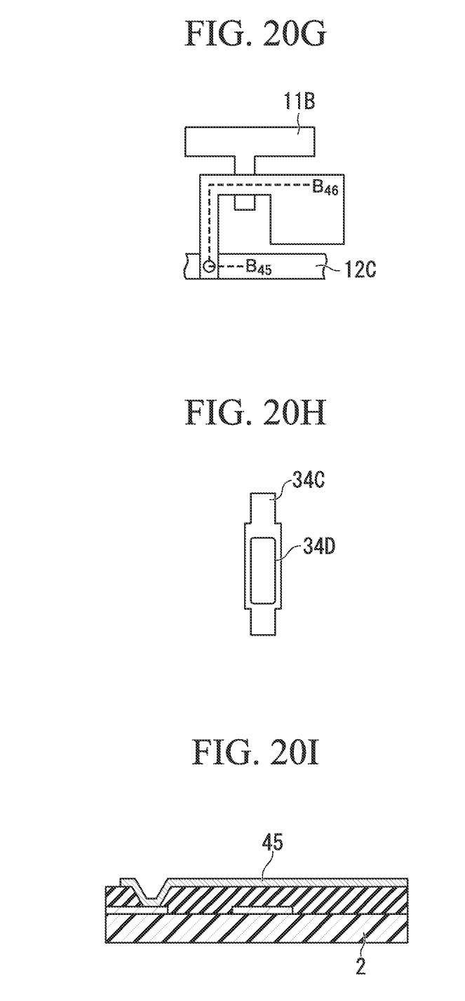

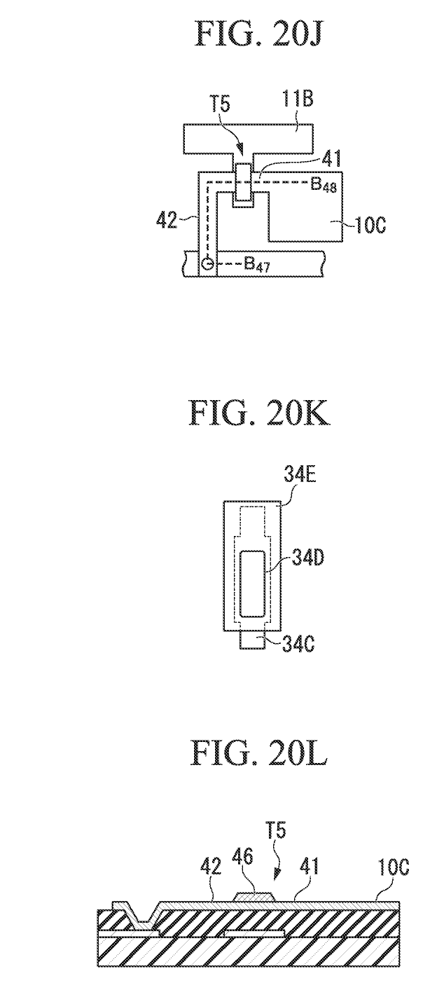

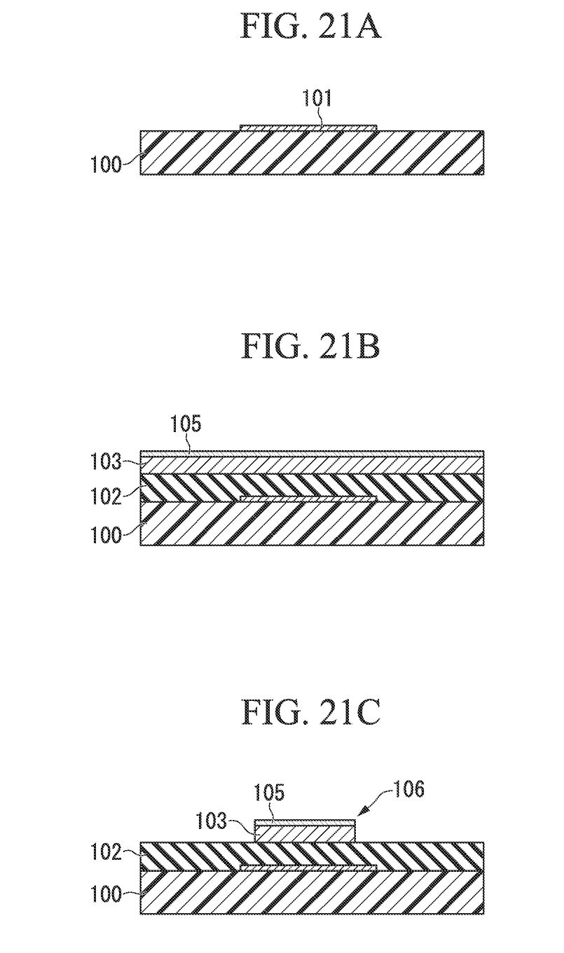

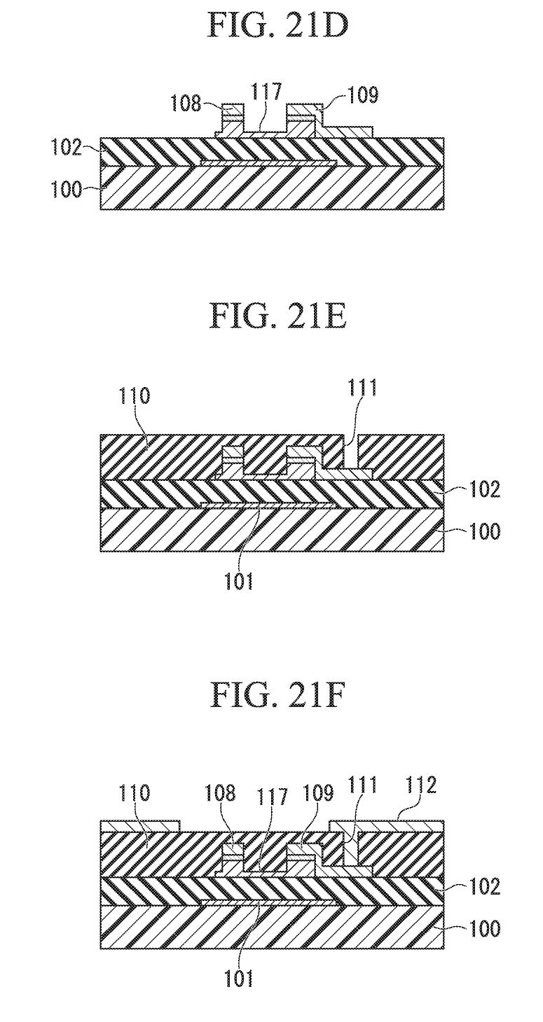

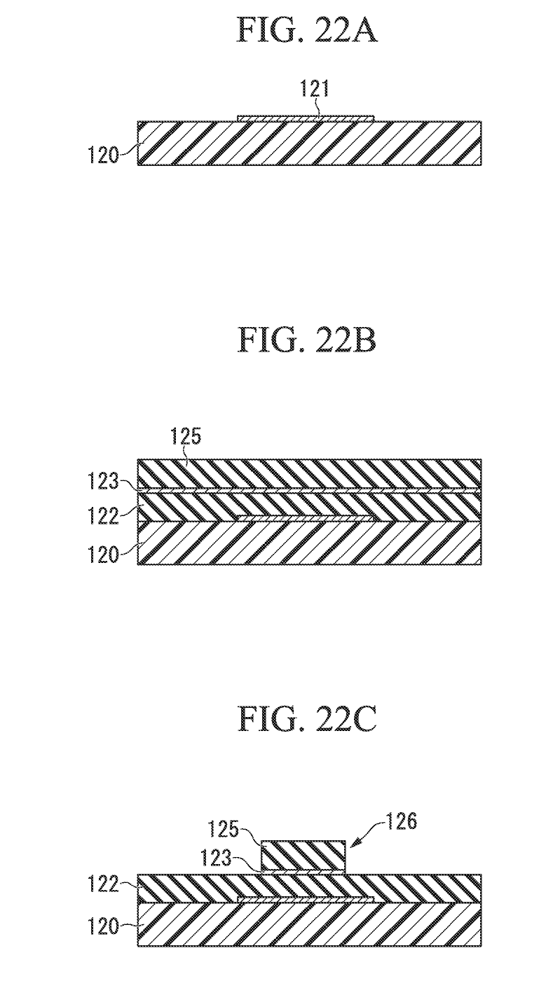

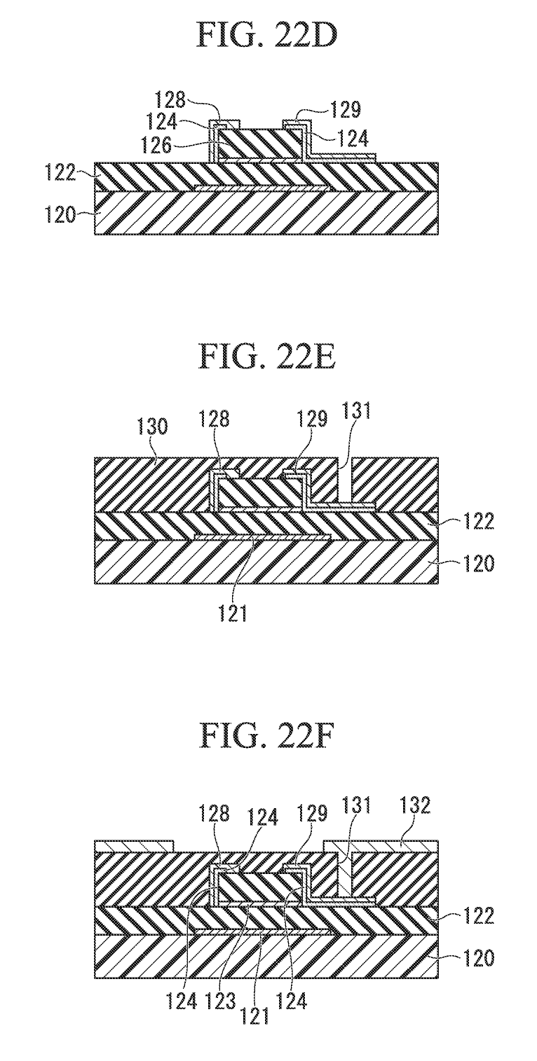

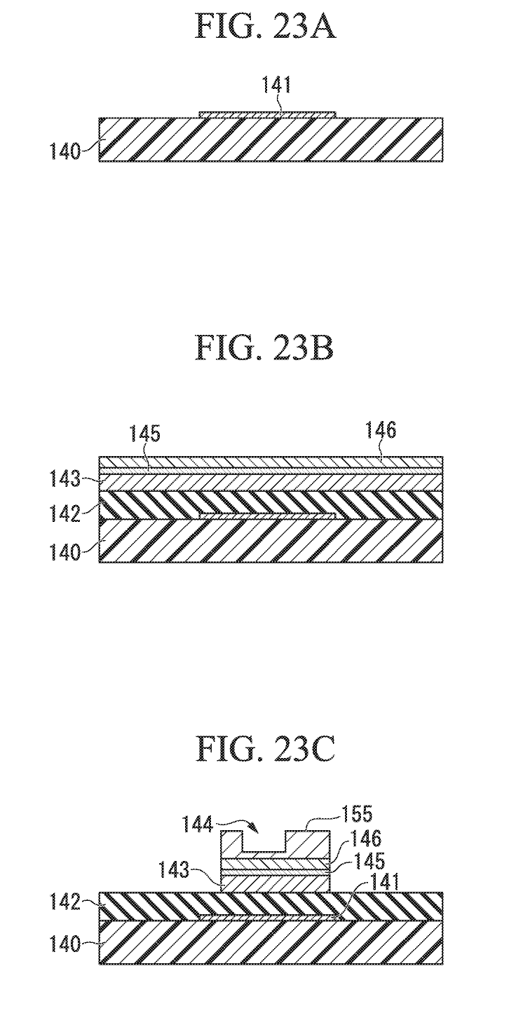

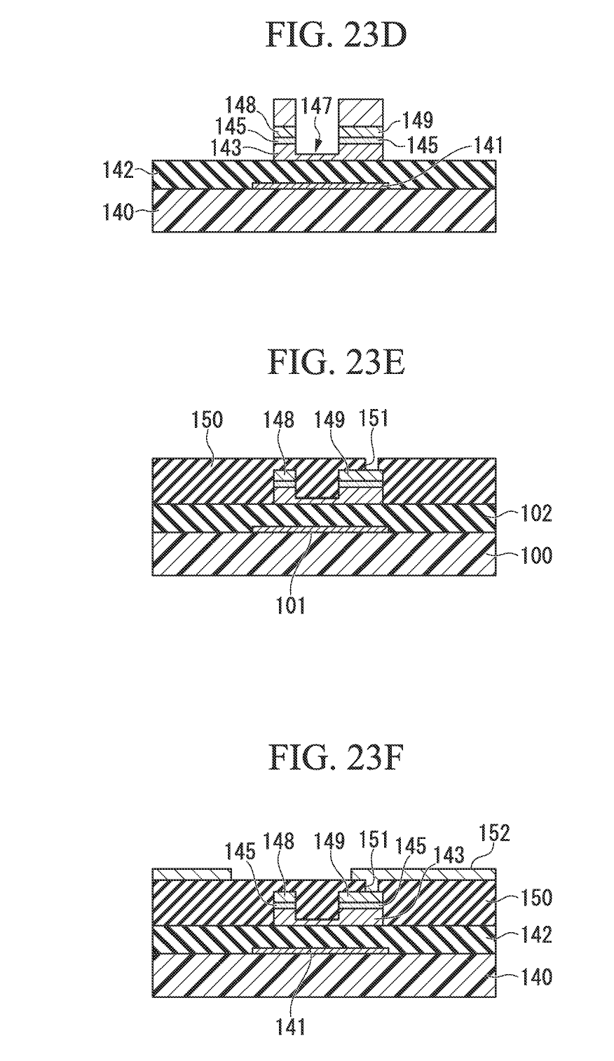

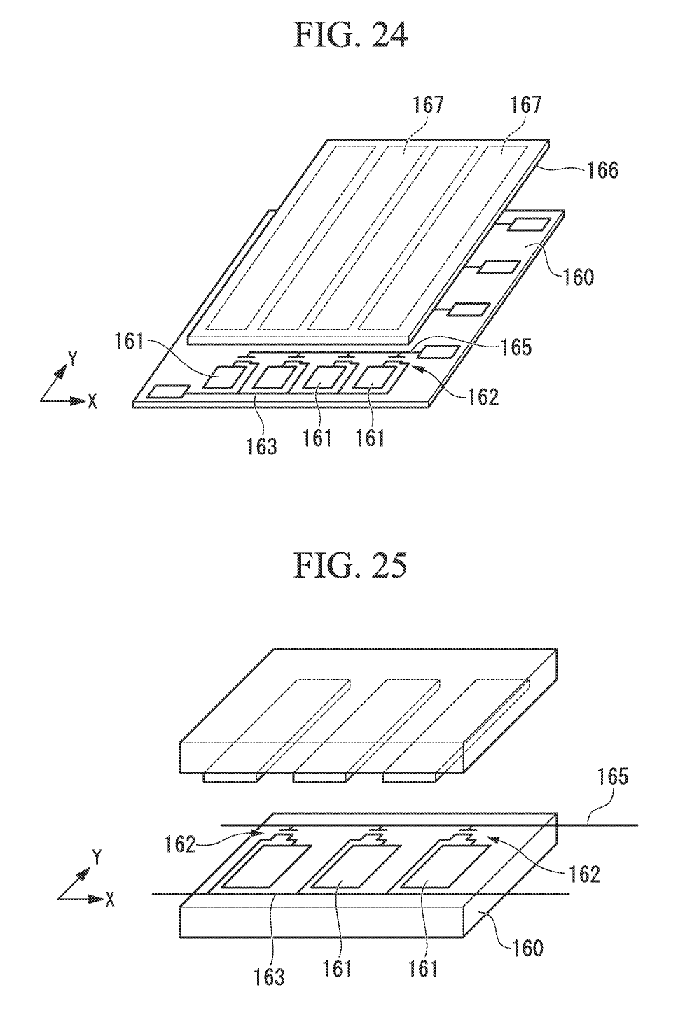

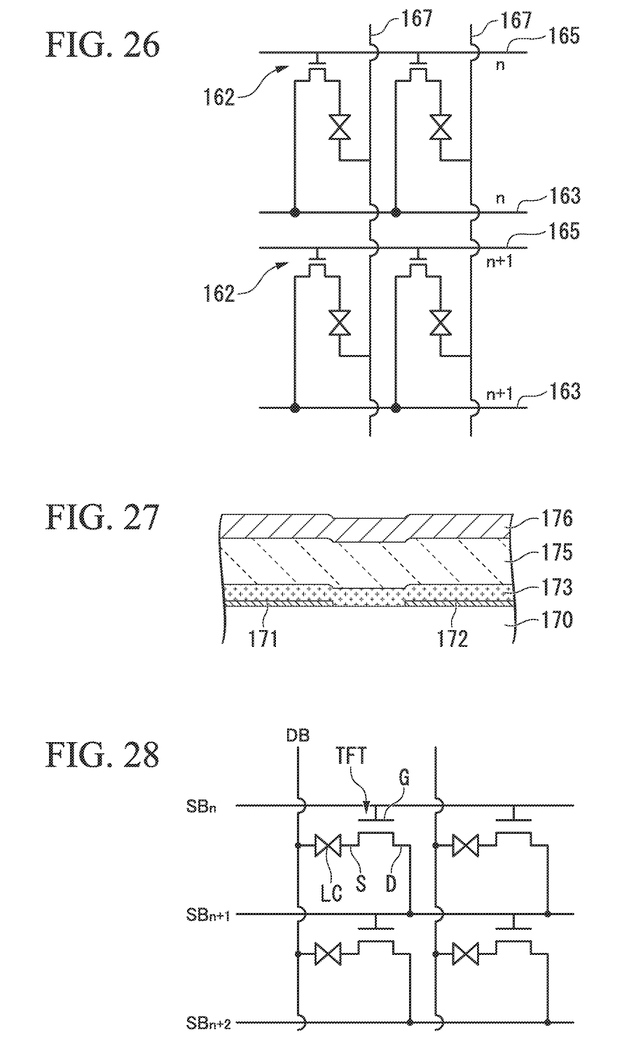

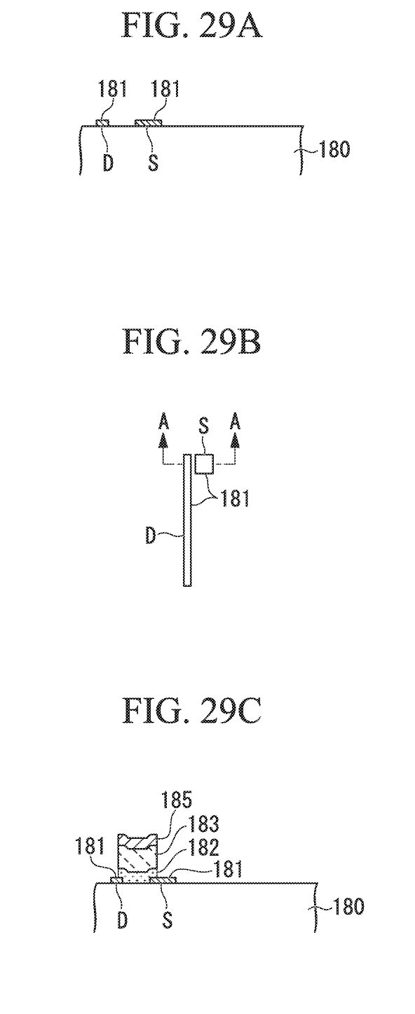

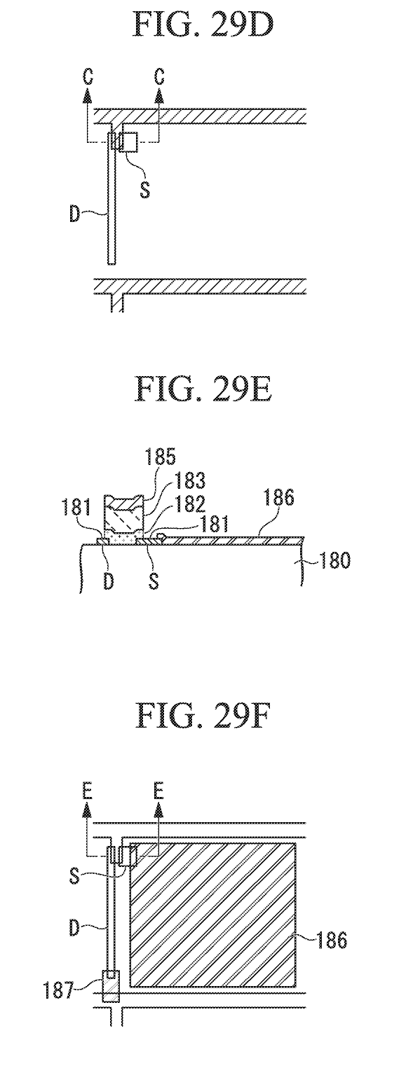

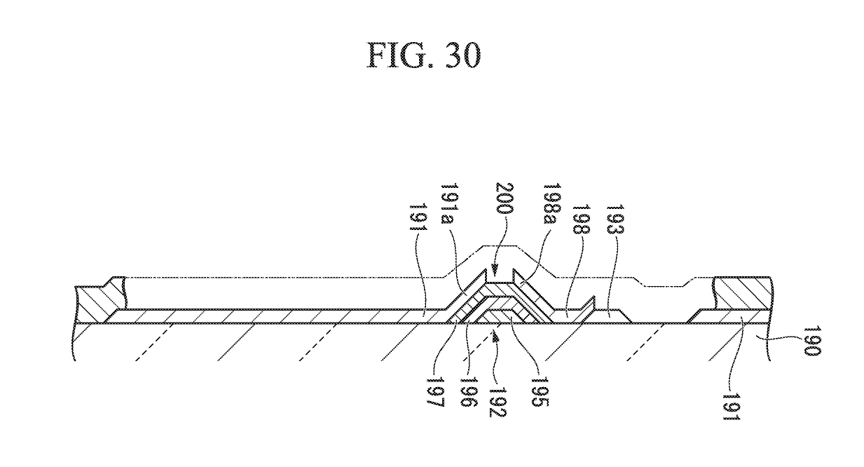

To manufacture the switching element T5 with the above-described constitution, as shown in FIG. 20A and FIG. 20C, a laminated film of Al/Mo is formed using sputtering over the insulating second substrate 2. Then, a first photolithography process step of resist coating, exposure, developing, wet etching, and resist peeling is performed to etch the Al/Mo layer. By doing this, the scanning line 11B having a gate electrode 31, and the reference signal line 12C are formed. Next, as shown in FIG. 20D and FIG. 20F, CVD is used to deposit the insulating film 33 having a laminated structure of a SiO₂/SiNₓ film. Then, a second photolithography process step of resist coating, exposure, developing, and dry etching is done. By doing this, the condition shown in FIG. 17D and FIG. 17F is obtained. Next, sputtering is done to deposit an IGZO film. Then, by resist coating, exposure, developing, and wet etching, an IGZO film 45 is processed to the shapes shown in FIGS. 20G and 20I, this being the pixel electrode shape, the source electrode shape, the island shape and the drain electrode shape passing over the gate electrode, and the connecting line shape. Then, resist coating, exposure, and developing are done to perform hydrogen plasma processing, in the condition with the covering by resist 46, of the island-shaped part that passes over the gate electrode.

By the hydrogen plasma processing, as shown in FIG. 20J and FIG. 20L, parts that are were not covered by resist are made conductive, the pixel electrode 10C, the source electrode 41, the drain electrode 43, and the connecting line 42 becoming conductors made of an IGZO reduced substance, thereby forming the switching element T5. The contact hole 34D is formed in the insulating film 33 deposited over the terminal part 34C, enabling the formation of a terminal by forming a terminal conductor 34E made of IGZO reduced substance.

By doing this, it is possible to fabricate a switching element T5 having the structure shown in FIG. 18A, FIG. 18B, and FIG. 19 on the second substrate 2, and to obtain a TFT array substrate by providing the gate driver 13.

According to the above-described fifth manufacturing method, it is possible to form the switching element T5 on the second substrate 2 by two deposition process steps using sputtering, one deposition step using CVD, four photolithography process steps, one dry etching process step, two wet etching process steps, and one hydrogen plasma processing steps.

Also, it is possible to have one CVD film deposition step and four photolithography process steps, and possible to achieve a reduction in the number of process steps.

According to the above-described manufacturing method, the n⁺a-Si layer of the conventional art is not required. For this reason, compared with the reverse-staggered type manufacturing method that required the n⁺a-Si layer, it is possible to achieve the effect of reducing the masks used in photolithography process steps.

Also, although there are four photolithography process steps in the above process, so that there are four masks, by using half-tone exposure it is possible to combine the process steps shown in FIG. 20G and FIG. 20I, in which case it is possible to achieve a further reduction in the number of process steps.

### INDUSTRIAL AVAILABILITY

The display device according to the present invention incorporates an oxide semiconductor layer in the switching element, and makes provides immunity to the effect of leakage current. Also, it is possible to make the pixel electrode in an opposing-data supply type display device and the electrode connected thereto of the same material and of films formed simultaneously, to reduce the process steps, thereby enabling the achievement of a reduction of the cost of LCD televisions and the like.

### REFERENCE SYMBOLS

1: First substrate
2: Second substrate
3: Data electrode
10, 10A, 10B, 10C: Pixel electrode
11, 11A, 11B: Scanning line
12, 12, 12B, 12C: Reference signal line
13: Gate driver
T1, T2, T3, T4, T5: Switching element (thin-film transistor)
20, 37, 41: Drain electrode
21, 39, 43: Source electrode
22, 35, 39: Oxide semiconductor layer
23: Insulating film
25: Drive IC

1. A display device comprising:
a first substrate;
a second substrate that is disposed in opposition to the first substrate;
a display medium layer that is provided between the first substrate and the second substrate;
a plurality of stripe-shaped data electrodes that are formed on the first substrate and that extend in the column direction;
a plurality of scanning lines and a plurality of reference signal lines that are formed on the second substrate and that extend in the row direction;
a plurality of pixel electrodes that are formed on the second substrate and that are disposed in a matrix arrangement;
a plurality of switching elements that are formed on the second substrate and in which on/off is controlled by the plurality of scanning lines, and that are disposed between the plurality of reference signal lines and the plurality of pixel electrodes; and
an oxide semiconductor layer that is disposed between a source electrode and a drain electrode;
wherein the switching elements are formed so as to be disposed in the vicinity of a gate electrode on the oxide semiconductor layer, with an insulating layer interposed therebetween;
the pixel electrodes are provided so as to be connected to the source electrode or the drain electrode;
the source electrode or the drain electrode that is connected to the pixel electrode is made from the same material as the pixel electrode; and
the source electrode and the drain electrode are films formed at the same time.

2. The display device according to claim 1, wherein,
by scanning the scanning lines, on/off control of the switching elements that are disposed along the corresponding scanning lines is performed;
a reference signal voltage is applied to the pixel electrodes from the reference signal lines, via the switching elements that are placed in the on state; and
each of data signals corresponding to the plurality of the data electrodes is input, thereby controlling a molecular orientation or a luminescence of the display medium layer that is interposed between the pixel electrodes and the data electrodes to which voltages are applied, so as to make a display.

3. The display device according to claim 1, wherein the pixel electrodes, the drain electrodes, and the source electrodes are made of an indium-gallium-zinc oxide reduced substance.

4. The display device according to claim 1, wherein the pixel electrodes, the drain electrodes, and the source electrodes and the reference signal lines and connecting lines that connect thereto and the reference signal lines are all made of indium-gallium-zinc oxide; and wherein
the oxide semiconductor layer is made of indium-gallium-zinc oxide.

5. The display device according to claim 1, further provided with a light-emitting diode backlight.

6. The display device according to claim 1, wherein the reference signal lines, the source electrodes or the drain electrodes of the switching elements connected to the reference signal lines, and the pixel electrodes and the drain electrodes or source electrodes of the switching elements connected to the pixel electrodes are all made of a transparent electrically conductive film, and
the oxide semiconductor layer interposed between the source electrodes and the drain electrodes is made of indium-gallium-zinc oxide.

7. The display device according to claim 6, wherein the plurality of reference signal lines, the source electrodes or drain electrodes of switching elements connected thereto, the pixel electrodes, and the drain electrodes or the source electrodes of switching elements connected to the pixel elements are all formed on the second substrate,
an insulating film is formed that covers the source electrodes, the drain electrodes, and the oxide semiconductor layer interposed therebetween, and
a gate electrode is formed on the insulating film.

8. The display device according to claim 6, wherein
a scanning line comprising the gate electrode and the reference signal line are formed on the second substrate,
an insulating film is formed that covers the scanning line and the reference signal line,
an oxide semiconductor layer is formed over the insulating film and over the gate electrode, and
a source electrode and a drain electrode and a pixel connected to any one thereof are formed on the insulating film.

9. The display device according to claim 6, wherein
a scanning line comprising the gate electrode and the reference signal line are formed on the second substrate,
an insulating film is formed that covers the scanning line and the reference signal line,
an oxide semiconductor layer is formed over the insulating film and over the gate electrode,
a source electrode and a drain electrode and a pixel connected to any one thereof are formed on the insulating film, and
wherein the oxide semiconductor layer is made of an indium-gallium-zinc oxide, and
the pixel electrode, and the source electrode and the drain electrode are made of an indium-gallium-zinc oxide reduced substance.

10. A method for manufacturing an array substrate, the method comprising:
on a second substrate disposed so as to be in opposition with a first substrate, forming a reference signal line and a source electrode or a drain electrode connected to the reference signal line, a pixel electrode, and a drain electrode or a source electrode connected to the pixel electrode, using a transparent electrically conductive material;
forming an oxide semiconductor layer so as to connect to the source electrode and the drain electrode;
forming an insulating film on the oxide semiconductor layer; and
forming a scanning line comprising a gate electrode on the second substrate so that the gate electrode is positioned on an insulating film between the source electrode and the drain electrode.

11. The method for manufacturing an array substrate according to claim 10, wherein the gate electrode and the scanning line are metal interconnects made of a metal material.

12. A method for manufacturing an array substrate, the method comprising:
on a second substrate disposed so as to be in opposition with a first substrate, forming a pixel electrode and a source electrode or a drain electrode connected to the pixel electrode, using a transparent electrically conductive material;
forming an oxide semiconductor layer so as to connect to the source electrode and the drain electrode;
forming an insulating film on the oxide semiconductor layer;
forming a scanning line comprising a gate electrode on the second substrate so that the gate electrode is positioned on an insulating film between the source electrode and the drain electrode; and
forming, on the insulating film, a reference signal line that connects to the one of the source electrode and the drain electrode that is not connected to the pixel electrode.

13. The method for manufacturing an array substrate according to claim 12, wherein the scanning line, the gate electrode and the reference signal line are metal interconnects made of a metal material.

14. A method for manufacturing an array substrate, the method comprising:
on a second substrate disposed so as to be in opposition with a first substrate, forming a reference signal line, a gate electrode, and a scanning line;
forming an insulating film so as to cover the reference signal line, the gate electrode, and the scanning line;
forming an oxide semiconductor layer on the insulating film on the gate electrode; and
forming a pixel electrode connected to one electrode of the source electrode and the gate electrode that sandwich the oxide semiconductor layer on the gate electrode from both sides.

15. The method for manufacturing an array substrate according to claim 14, wherein the scanning line, the gate electrode, and the reference signal line are metal interconnects made of a metal material.

16. The method for manufacturing an array substrate according to claim 14, wherein
a channel-protection film is formed over the oxide semiconductor layer after forming the oxide semiconductor layer,
a film is deposited for formation of the source electrode and the gate electrode, and
the film is patterned to form the source electrode and the gate electrode.

17. A method for manufacturing an array substrate, the method comprising:
on a second substrate disposed so as to be in opposition with a first substrate, forming a reference signal line, a gate electrode, and a scanning line;
forming an insulating film so as to cover the reference signal line, the gate electrode, and the scanning line;
forming an indium-gallium-zinc oxide layer so as to occupy the insulating film over the gate electrode, a pixel electrode formation position, a gate electrode formation position, and a source electrode formation position; and
reducing the part of the indium-gallium-zinc oxide layer other than the position over the gate electrode to make it conductive.

18. The method for manufacturing an array substrate according to claim 17, wherein plasma processing in a hydrogen atmosphere is performed as the reducing of the indium-gallium-zinc oxide layer.

19. The method for manufacturing an array substrate according to claim 17, wherein the scanning line, the gate electrode, and the reference signal line are metal interconnects made of a metal material.

20. The method for manufacturing an array substrate according to claim 10, the method comprising:
forming a display medium layer between the first substrate and the second substrate;
forming, on the first substrate, a plurality of stripe-shaped data electrodes extending in a column direction;
forming, of the second substrate, a plurality of scanning lines and a plurality of reference signal lines extending in a row direction;
forming, on the second substrate, a plurality of pixel electrode disposed in a matrix arrangement;
forming, on the second substrate, a plurality of switching elements that are on/off controlled by the plurality of scanning lines and that also are provided between the plurality of reference signal lines and the plurality of pixel electrodes; and
forming, on the second substrate, the reference signal lines, the pixel electrodes, and the switching elements.
